(19) United States
(12) Patent Application Publication
(10) Pub. No.: US 2025/0293083 A1
(43) Pub. Date: Sep. 18, 2025

(54) METHOD FOR FABRICATING SEMICONDUCTOR DEVICE

(71) Applicant: Samsung Electronics Co., Ltd., Suwon-si (KR)

(72) Inventors: Jong Soon PARK, Suwon-si (KR); Won Suk LEE, Suwon-si (KR); Hyon Wook RA, Suwon-si (KR); Sang Hyun LEE, Suwon-si (KR)

(73) Assignee: Samsung Electronics Co., Ltd., Suwon-si (KR)

(21) Appl. No.: 18/925,665

(22) Filed: Oct. 24, 2024

(30) Foreign Application Priority Data
Mar. 13, 2024 (KR) 10-2024-0035184
May 9, 2024 (KR) 10-2024-0060949

(51) Int. Cl. H01L 21/768

(52) U.S. Cl. CPC H01L 21/76816; H01L 21/76877

(57) ABSTRACT

A method for fabricating a semiconductor device includes sequentially forming an insulating material layer and a lower mask material layer on an upper surface of the substrate, forming first and second middle mask patterns on an upper surface of the lower mask material layer forming a spacer material layer on the upper surface of the lower mask material layer, a sidewall and an upper surface of the first middle mask pattern, and a sidewall and an upper surface of the second middle mask pattern, forming a first upper mask material layer on an upper surface of the spacer material layer, forming a first photoresist pattern having a first hole pattern on an upper surface of the first upper mask material layer for exposing a portion of the first upper mask material layer between the first and second middle mask patterns.

### CROSS-REFERENCE TO RELATED APPLICATIONS

This U.S. non-provisional application claims priority under 35 U.S.C. § 119 to Korean Patent Application No. 10-2024-0035184 filed on Mar. 13, 2024, and Korean Patent Application No. 10-2024-0060949 filed on May 9, 2024, in the Korean Intellectual Property Office. The entire contents of both these applications are herein incorporated by reference.

### BACKGROUND

Example embodiments of relate to a method for fabricating a semiconductor device, and more particularly, to a method for fabricating a semiconductor device including a plurality of wiring patterns.

Due to the development of electronic technology, down-scaling of a semiconductor device has progressed rapidly, thereby requiring high integration and low power consumption of a semiconductor chip. As a pitch between circuit components such as wiring patterns decreases, reliability of the wiring pattern is also reduced. For this reason, research is underway to improve the reliability of the wiring pattern.

### SUMMARY

Example embodiments are directed to a method for fabricating a semiconductor device that includes forming a plurality of wiring patterns with improved reliability.

According to example embodiments, a method for fabricating a semiconductor device includes sequentially forming an insulating material layer and a lower mask material layer on an upper surface of a substrate, and forming first and second middle mask patterns on an upper surface of the lower mask material layer. The second middle mask pattern is spaced apart from the first middle mask pattern in a first horizontal direction, and each of the first and second middle mask patterns extends in a second horizontal direction different from the first horizontal direction. The method further includes forming a spacer material layer on each of the upper surface of the lower mask material layer, a sidewall and an upper surface of the first middle mask pattern, and a sidewall and an upper surface of the second middle mask pattern, forming a first upper mask material layer on an upper surface of the spacer material layer, forming a first photoresist pattern having a first hole pattern on an upper surface of the first upper mask material layer, the first hole pattern exposing a portion of the first upper mask material layer between the first and second middle mask patterns, etching the first upper mask material layer through the first hole pattern to form a first trench exposing a portion of the spacer material layer between the first and second middle mask patterns, forming a sacrificial pattern on the spacer material layer in the first trench, etching the first upper mask material layer, etching the portion of the spacer material layer such that a portion of the upper surface of the lower mask material layer between the first and second middle mask patterns is exposed, wherein a portion of the spacer material layer remaining on the sidewall of each of the first and second middle mask patterns and a lower surface of the sacrificial pattern is defined as a spacer pattern, etching the first and second middle mask patterns, etching the lower mask material layer using the spacer pattern and the sacrificial pattern as a mask, wherein a remaining portion of the lower mask material layer is defined as a lower mask pattern, etching the insulating material layer using the lower mask pattern as a mask, wherein a remaining portion of the insulating material layer is defined as an insulating pattern, and forming each of a plurality of wiring patterns between adjacent ones of the insulating patterns. The plurality of wiring patterns include a first wiring pattern, a second wiring pattern spaced apart from the first wiring pattern in the first horizontal direction, and a third wiring pattern spaced apart from the second wiring pattern in the second horizontal direction.

According to example embodiments, a method for fabricating a semiconductor device includes sequentially forming an insulating material layer and a lower mask material layer on an upper surface of the substrate, and forming first and second middle mask patterns on an upper surface of the lower mask material layer. The second middle mask pattern is spaced apart from the first middle mask pattern in a first horizontal direction, and each of the first and second middle mask patterns extend in a second horizontal direction different from the first horizontal direction. The method further includes conformally forming a spacer material layer on each of the upper surface of the lower mask material layer, a sidewall and an upper surface of the first middle mask pattern, and a sidewall and an upper surface of the second middle mask pattern, forming a first photoresist pattern having a first hole pattern on the spacer material layer between the first and second middle mask patterns, forming a first trench under the first hole pattern, the first trench defined by the spacer material layer, forming a sacrificial pattern on the spacer material layer in the first trench, and etching the portion of the spacer material layer such that a portion of the upper surface of the lower mask material layer between the first and second middle mask patterns is exposed. A portion of the spacer material layer remaining on the sidewall of each of the first and second middle mask patterns and a lower surface of the sacrificial pattern forms a spacer pattern. The method further includes etching the first and second middle mask patterns, and etching the lower mask material layer using the spacer pattern and the sacrificial pattern as a mask. A remaining portion of the lower mask material layer forms a lower mask pattern. The method still further includes etching the insulating material layer using the lower mask pattern as a mask, wherein a remaining portion of the insulating material layer is defined as an insulating pattern, and forming each of a plurality of wiring patterns between adjacent ones of the insulating patterns. The sacrificial pattern includes a material different from a material of the spacer material layer.

According to example embodiments, a method for fabricating a semiconductor device includes sequentially forming an insulating material layer, a first lower mask material layer, and a second lower mask material layer on an upper surface of a substrate, forming first and second middle mask patterns on an upper surface of the second lower mask material layer, the second middle mask pattern spaced apart from the first middle mask pattern in a first horizontal direction, each of the first and second middle mask patterns extending in a second horizontal direction different from the first horizontal direction, conformally forming a spacer material layer on each of the upper surface of the second lower mask material layer, a sidewall and an upper surface of the first middle mask pattern, and a sidewall and an upper surface of the second middle mask pattern, forming a first upper mask material layer on an upper surface of the spacer material layer, forming a first photoresist pattern having a first hole pattern exposing a portion of the first upper mask material layer between the first and second middle mask patterns on an upper surface of the first upper mask material layer, wherein a width in the first horizontal direction of the first hole pattern is less than a pitch in the first horizontal direction between the first and second middle mask patterns, etching the first upper mask material layer through the first hole pattern to form a first trench exposing a portion of the spacer material layer between the first and second middle mask patterns, forming a sacrificial pattern on the spacer material layer in the first trench, etching the first upper mask material layer, etching a portion of the spacer material layer such that a portion of the upper surface of the second lower mask material layer between the first and second middle mask patterns is exposed, wherein a portion of the spacer material layer remaining on the sidewall of each of the first and second middle mask patterns and a lower surface of the sacrificial pattern forms a spacer pattern, etching the first and second middle mask patterns, and etching each of the first and second lower mask material layers using the spacer pattern and the sacrificial pattern as a mask. Remaining portions of the first and second lower mask material layers form first and second lower mask patterns, respectively. The method includes etching the insulating material layer using the first and second lower mask patterns as a mask, wherein a remaining portion of the insulating material layer forms an insulating pattern, and forming each of a plurality of wiring patterns between adjacent ones of the insulating patterns. The plurality of wiring patterns include a first wiring pattern, a second wiring pattern spaced apart from the first wiring pattern in the first horizontal direction, and a third wiring pattern spaced apart from the second wiring pattern in the second horizontal direction. A pitch in the second horizontal direction between the second and third wiring patterns is equal to a width in the second horizontal direction of the sacrificial pattern. The sacrificial pattern includes a material different from a material of the spacer material layer.

### BRIEF DESCRIPTION OF DRAWINGS

The above and other aspects and/or features of the example embodiments disclosed herein will become more apparent by describing in detail some example embodiments thereof with reference to the attached drawings.

FIG. 1 is a layout diagram for illustrating a semiconductor device, according to some example embodiments of the inventive concepts.

FIG. 2 is a cross-sectional view taken along a line A-A′ in FIG. 1.

FIG. 3 is a cross-sectional view taken along a line B-B′ in FIG. 1.

FIGS. 4, 5, 6, 7, 8, 9, 10, 11, 12,13, 14, 15, 16, 17, 18, 19, 20, 21, 22, 23, 24, 25, 26, 27, and 28 illustrate intermediate structures corresponding to intermediate operations of a method for fabricating a semiconductor device, according to some example embodiments of the inventive concepts.

FIG. 29 is a layout diagram for illustrating a semiconductor device, according to some example embodiments of the inventive concepts.

FIG. 30 is a layout diagram for illustrating a semiconductor device, according to some example embodiments of the inventive concepts.

FIG. 31 is a cross-sectional view taken along a line C-C′ in FIG. 30.

FIG. 32 is a cross-sectional view taken along a line D-D′ in FIG. 30.

FIG. 33 is a cross-sectional view taken along a line E-E′ in FIG. 30.

FIG. 34 is a cross-sectional view taken along the line F-F′ in FIG. 30.

FIGS. 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, and 89 illustrate intermediate structures corresponding to intermediate operations of a method for fabricating a semiconductor device, according to some example embodiments of the inventive concepts.

FIG. 90 is a layout diagram for illustrating a semiconductor device, according to some example embodiments of the inventive concepts.

FIG. 91 is a layout diagram for illustrating a semiconductor device, according to some example embodiments of the inventive concepts.

FIG. 92 and FIG. 93 illustrate intermediate structures corresponding to intermediate operations of a method for fabricating a semiconductor device, according to some example embodiments of the inventive concepts.

FIG. 94 is a layout diagram for illustrating a semiconductor device, according to some example embodiments of the inventive concepts.

FIG. 95 and FIG. 96 illustrate intermediate structures corresponding to intermediate operations of a method for fabricating a semiconductor device, according to some example embodiments of the inventive concepts.

### DETAILED DESCRIPTION

In the drawings, the thickness of layers, films, panels, regions, etc., are exaggerated for clarity. In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

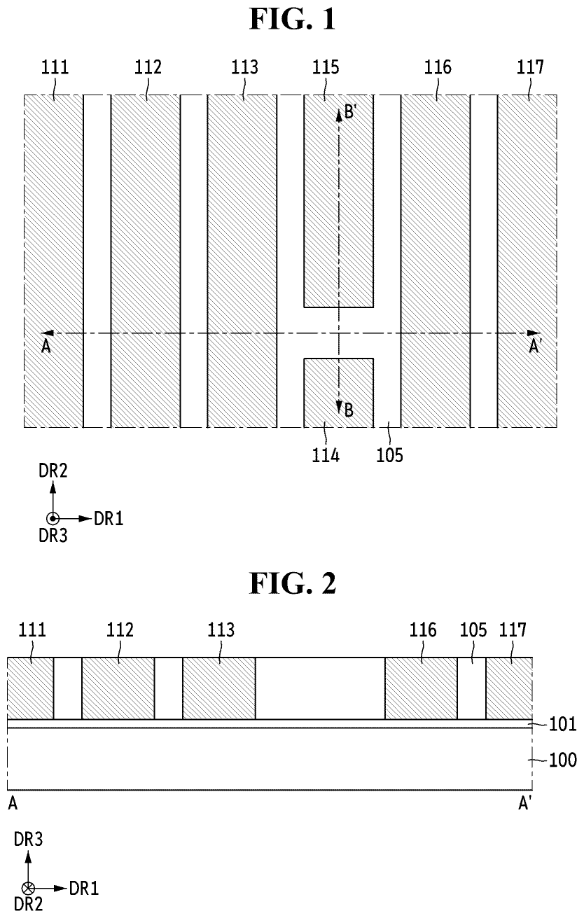

Hereinafter, a semiconductor device according to example embodiments of the inventive concepts is described with reference to FIG. 1 to FIG. 3.

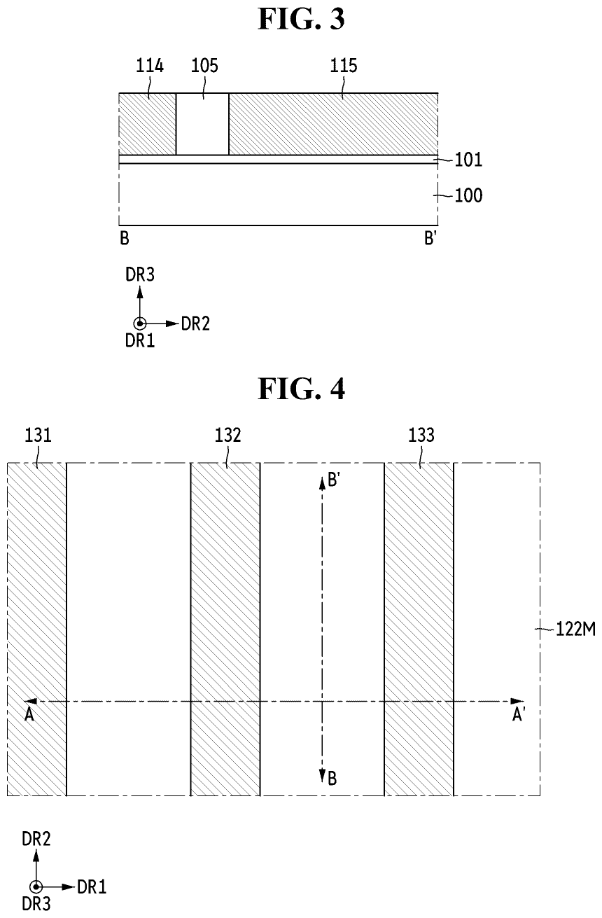

FIG. 1 illustrates a layout of a semiconductor device according to some example embodiments of the inventive concepts. FIG. 2 is a cross-sectional view taken along a line A-A′ in FIG. 1. FIG. 3 is a cross-sectional view taken along a line B-B′ in FIG. 1.

Referring to FIGS. 1, 2, and 3, the semiconductor device includes a substrate 100, an etching stop layer 101, an insulating pattern 105, and first to seventh wiring patterns 111 to 117.

The substrate 100 may have a structure in which a base substrate and an epitaxial layer is deposited thereon. However, the example embodiments are not limited thereto. The substrate 100 may be a silicon substrate, a gallium arsenide substrate, a silicon germanium substrate, a ceramic substrate, a quartz substrate, or a glass substrate for a display, or may be a SOI (Semiconductor On Insulator) substrate. The substrate 100 may include a conductive pattern. The conductive pattern may be a metal wiring or a contact, or a gate electrode of a transistor, a source/drain of a transistor, or a diode. However, the example embodiments are not limited thereto, and the substrate 100 may include other materials and may include other features and patterns depending on application and/or design.

Example embodiments are discussed hereinafter, with respect to a 3-D frame of reference including a first horizontal direction DR1 and a second horizontal direction DR2 each of which may be defined as a direction parallel to an upper surface of the substrate 100, and a vertical direction DR3 that may be defined as a direction perpendicular to each in the first horizontal direction DR1 and the second horizontal direction DR2. The second horizontal direction DR2 is orthogonal to the first horizontal direction DR1. The vertical direction DR3 is orthogonal to the first horizontal direction DR1 and the second horizontal direction DR2. The vertical direction DR3 may be defined as a direction perpendicular to the upper surface of the substrate 100.

An etching stop layer 101 may be disposed on the upper (or top) surface of the substrate 100. The etching stop layer 101 may contact (e.g., directly contact) the upper surface of the substrate 100. For example, the etching stop layer 101 may be formed conformally. In FIG. 2 and FIG. 3, the etching stop layer 101 is shown as being formed as a single film. However, the example embodiments are not limited thereto. In other example embodiments, the etching stop layer 101 may be or include a stack of multi-films. For example, the etching stop layer 101 may be or include at least one of aluminum nitride (AlN), aluminum oxide (AlO), hafnium oxide (HfO), zirconium oxide (ZrO), hafnium nitride (HfN), zirconium nitride (ZrN), silicon oxide (SiO₂), silicon nitride (SiN), silicon oxynitride (SiCN), silicon oxycarbide (SiOC), silicon carbide (SiC), a low dielectric constant material, and a combination of two or more thereof.

Each of the first to seventh wiring patterns 111 to 117 may be disposed on an upper surface of the etching stop layer 101. For example, each of the first to seventh wiring patterns 111 to 117 may contact the upper (or top) surface of the etching stop layer 101. Each of the first to seventh wiring patterns 111 to 117 may extend in the second horizontal direction DR2. For example, the second wiring pattern 112 may be spaced (or distanced) from the first wiring pattern 111 in the first horizontal direction DR1. The third wiring pattern 113 may be spaced (or distanced) from the second wiring pattern 112 in the first horizontal direction DR1. Each of the fourth wiring pattern 114 and the fifth wiring pattern 115 may be spaced (or separated) from the third wiring pattern 113 in the first horizontal direction DR1. The fifth wiring pattern 115 may be spaced (or separated) from the fourth wiring pattern 114 in the second horizontal direction DR2. The sixth wiring pattern 116 may be spaced (or separated) from each of the fourth wiring pattern 114 and the fifth wiring pattern 115 in the first horizontal direction DR1. The seventh wiring pattern 117 may be spaced (or separated) from the sixth wiring pattern 116 in the first horizontal direction DR1. Thus, each of the wiring patterns 111, 112, 113, 114, 115, 116, and 117 are separated from one or more adjacent wiring patterns such that a gap is defined therebetween.

For example, widths in the first horizontal direction DR1 of the first to seventh wiring patterns 111 to 117 may be equal to each other. However, example embodiments are not limited thereto, and the first to seventh wiring patterns 111 to 117 may have different widths. For example, upper surfaces of the first to seventh wiring patterns 111 to 117 may be coplanar with each other. For example, as shown in FIG. 1, a short side of the fourth wiring pattern 114 facing (e.g., directly opposite to) the fifth wiring pattern 115 in the second horizontal direction DR2 may be perpendicular to each of a long side of the fourth wiring pattern 114 facing (e.g., directly opposite to) the third wiring pattern 113 in the first horizontal direction DR1 and a long side of the fourth wiring pattern 114 facing (e.g., directly opposite to) the sixth wiring pattern 116 in the first horizontal direction DR1. As shown in FIG. 1, a short side of the fifth wiring pattern 115 facing (e.g., directly opposite to) the fourth wiring pattern 114 in the second horizontal direction DR2 may be perpendicular to each of a long side of the fifth wiring pattern 115 facing (e.g., directly opposite to) the third wiring pattern 113 in the second horizontal direction DR2 and a long side of the fifth wiring pattern 115 facing (e.g., directly opposite to) the sixth wiring pattern 116 in the second horizontal direction DR2.

Each of the first to seventh wiring patterns 111 to 117 may be or include a conductive material. For example, each of the first to seventh wiring patterns 111 to 117 may include one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), copper (Cu), carbon (C), silver (Ag), cobalt (Co), indium (In), tin (Sn), zinc (Zn), manganese (Mn), magnesium (Mg), chromium (Cr), germanium (Ge), strontium (Sr), platinum (Pt), aluminum (Al), ruthenium (Ru), iridium (Ir), rhodium (Rh), and combinations thereof. However, example embodiments are not limited thereto, and the first to seventh wiring patterns 111 to 117 may be or include other materials depending on application and/or design.

An insulating pattern 105 may be disposed on the upper (or top) surface of the etching stop layer 101. The insulating pattern 105 may contact (e.g., directly) the upper surface of the etching stop layer 101. The insulating pattern 105 may surround a sidewall of each of the first to seventh wiring patterns 111 to 117. For example, the insulating pattern 105 may be disposed between the fourth wiring pattern 114 and the fifth wiring pattern 115. For example, an upper surface of the insulating pattern 105 may be coplanar with the upper surface of each of the first to seventh wiring patterns 111 to 117. However, the example embodiments are not limited thereto.

In some example embodiments, the insulating pattern 105 may include at least one of silicon oxide, silicon nitride, silicon oxynitride, and a low dielectric constant material. The low dielectric constant material may include, for example, tetraethyl orthosilicate (TEOS), fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), TOSZ (Tonen SilaZen), FSG (fluoride silicate glass), polyimide nanofoams such as polypropylene oxide, CDO (carbon doped silicon oxide), OSG (organo silicate glass), SiLK, amorphous fluorinated carbon, silica aerogels, silica xerogels, mesoporous silica, or combinations thereof. However, the low dielectric constant material may also include other materials, depending on application and/or design.

Hereinafter, a method for fabricating a semiconductor device according to some embodiments of the present disclosure is described with reference to FIG. 1 to FIG. 28.

FIG. 4 to FIG. 28 illustrate intermediate structures corresponding to intermediate operations of a method for fabricating a semiconductor device according to some example embodiments of the inventive concepts. It is understood that additional operations can be provided before, during, and/or after the operations discussed below, and some of the operations described below can be replaced or eliminated, for additional embodiments of the inventive concepts. The order of the operations/processes may be interchangeable, or two or more operations/processes can be performed simultaneously.

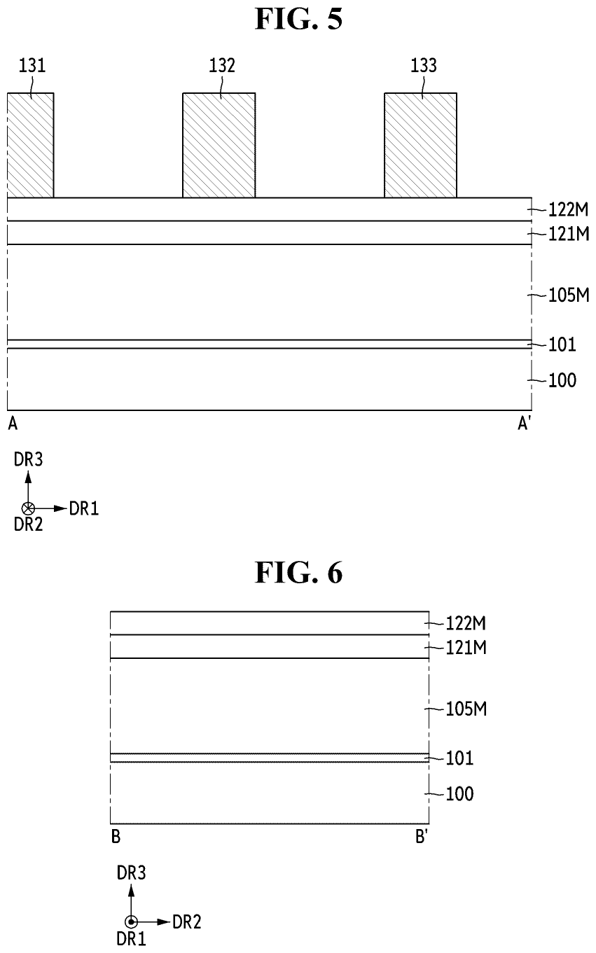

FIG. 4 illustrates a layout of an intermediate structure. FIG. 5 is the cross-sectional view of the intermediate structure in FIG. 4 taken along line A-A′. FIG. 6 is the cross-sectional view of the intermediate structure in FIG. 4 taken along line B-B′. Referring to FIG. 4 to FIG. 6, the etching stop layer 101, an insulating material layer 105M, a first lower mask material layer 121M, and a second lower mask material layer 122M may be formed sequentially on the upper surface of the substrate 100. For example, the etching stop layer 101 may contact (e.g., directly) the upper surface of the substrate 100. The first lower mask material layer 121M may contact (e.g., directly) the upper surface of the etching stop layer 101. The second lower mask material layer 122M may contact (e.g., directly) an upper surface of the first lower mask material layer 121M. For example, each of the etching stop layer 101, the first lower mask material layer 121M, and the second lower mask material layer 122M may be formed conformally.

For example, the insulating material layer 105M may include at least one of silicon oxide, silicon nitride, silicon oxynitride, a low dielectric constant material, and combination thereof. For example, the first lower mask material layer 121M may include titanium nitride (TiN). In some example embodiments, the first lower mask material layer 121M may include silicon nitride (SiN) or silicon oxynitride (SiON). The second lower mask material layer 122M may include a material different from that of the first lower mask material layer 121M. For example, the second lower mask material layer 122M may include TEOS (TetraEthylOthoSilicate). In some other example embodiments, the second lower mask material layer 122M may include silicon oxide (SiO₂). In some example embodiments, the second lower mask material layer 122M may be omitted.

Subsequently, first to third middle mask patterns 131, 132, and 133 may be formed on an upper surface of the second lower mask material layer 122M. Each of the first to third middle mask patterns 131, 132, and 133 may contact the upper surface of the second lower mask material layer 122M. For example, each of the first to third middle mask patterns 131, 132, and 133 may extend in the second horizontal direction DR2. The second middle mask pattern 132 may be spaced from the first middle mask pattern 131 in the first horizontal direction DR1. The third middle mask pattern 133 may be spaced from the second middle mask pattern 132 in the first horizontal direction DR1. For example, upper surfaces of the first to third middle mask patterns 131, 132, and 133 may be coplanar with each other. For example, each of the first to third middle mask patterns 131, 132, and 133 may include polysilicon or polycrystalline silicon.

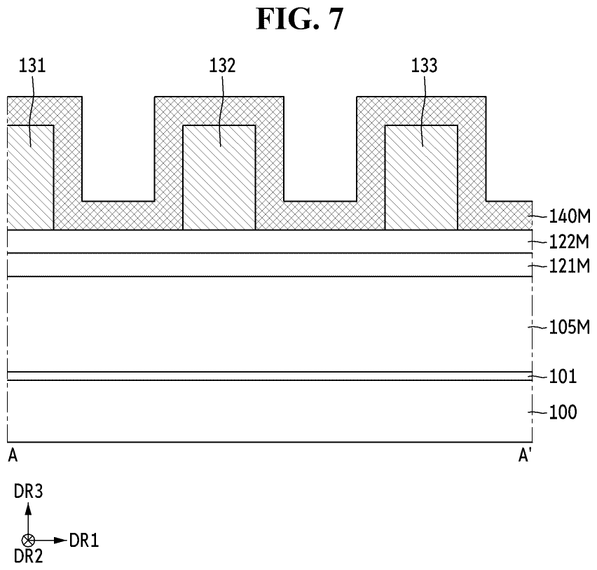

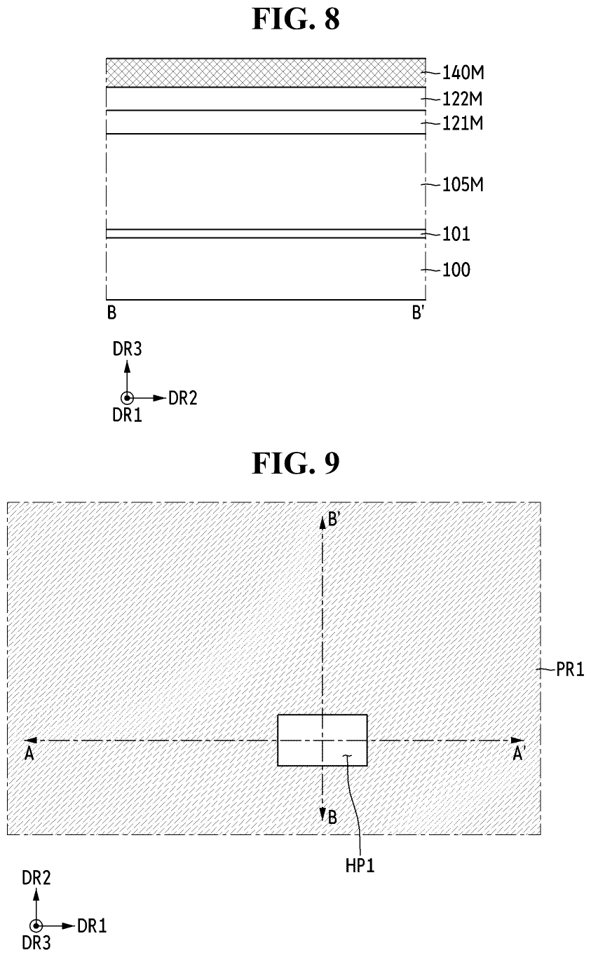

FIGS. 7 and 8 illustrate cross-sectional views in FIGS. 5 and 6, respectively, including a spacer material layer 140M formed on the first to third middle mask patterns 131, 132, and 133. Referring to FIG. 7 and FIG. 8, the spacer material layer 140M may be formed on a sidewall and the upper surface of each of the first to third middle mask patterns 131, 132, and 133. In addition, the spacer material layer 140M may be formed on the upper surface of the second lower mask material layer 122M. For example, the spacer material layer 140M may be conformally formed. The spacer material layer 140M may include a material different from that of each of the first to third middle mask patterns 131, 132, and 133. For example, the spacer material layer 140M may include titanium oxide (TiO₂). In some example embodiments, the spacer material layer 140M may include titanium nitride (TiN), amorphous carbon layer (ACL), silicon oxide (SiO₂), or a combination thereof.

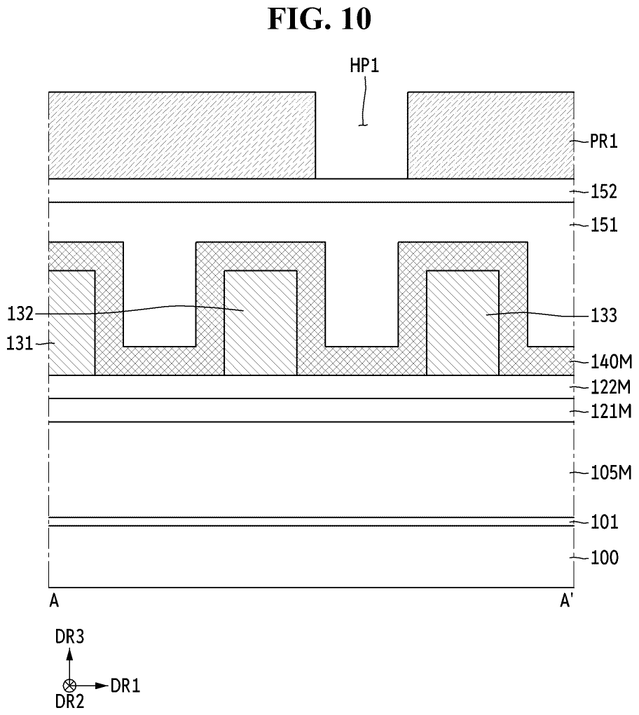

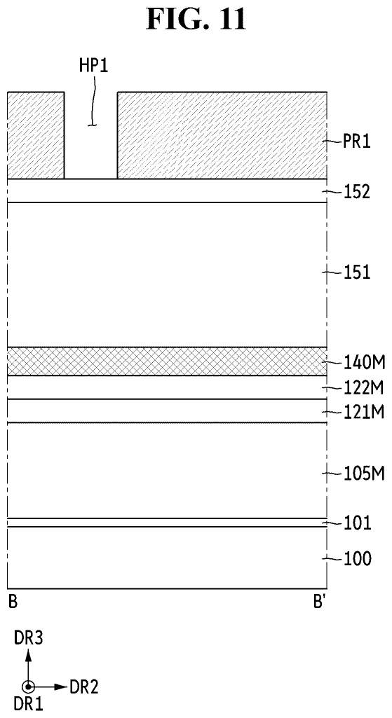

FIG. 9 illustrates a layout of an intermediate structure. FIG. 10 is the cross-sectional view of the intermediate structure in FIG. 9 taken along line A-A′. FIG. 11 is the cross-sectional view of the intermediate structure in FIG. 9 taken along line B-B′. Referring to FIG. 9 to FIG. 11, a first upper mask material layer 151 and a second upper mask material layer 152 may be formed sequentially on an upper surface of the spacer material layer 140M. For example, the first upper mask material layer 151 may contact the spacer material layer 140M. For example, the upper surface of the first upper mask material layer 151 may be formed to be flat (or planar). For example, the first upper mask material layer 151 may include SOH (Spin-On Hardmask). The second upper mask material layer 152 may contact an upper surface of the first upper mask material layer 151. For example, the second upper mask material layer 152 may be formed conformally. For example, the second upper mask material layer 152 may include silicon oxynitride (SiON) or silicon nitride (SiN).

Subsequently, a first photoresist pattern PR1 including a first hole pattern HP1 may be formed on an upper surface of the second upper mask material layer 152. For example, the first hole pattern HP1 may extend through the first photoresist pattern PR1 in the vertical direction DR3. For example, the first hole pattern HP1 may be formed between the second middle mask pattern 132 and the third middle mask pattern 133. A portion of the upper surface of the second upper mask material layer 152 disposed between the second middle mask pattern 132 and the third middle mask pattern 133 may be exposed through the first hole pattern HP1. For example, a width in the first horizontal direction DR1 of the first hole pattern HP1 may be smaller than a pitch (separation) in the first horizontal direction DR1 between the second middle mask pattern 132 and the third middle mask pattern 133. For example, the first hole pattern HP1 is offset from each of the second middle mask pattern 132 and the third middle mask pattern 133 and does not overlap each of the second middle mask pattern 132 and the third middle mask pattern 133 in the vertical direction DR3.

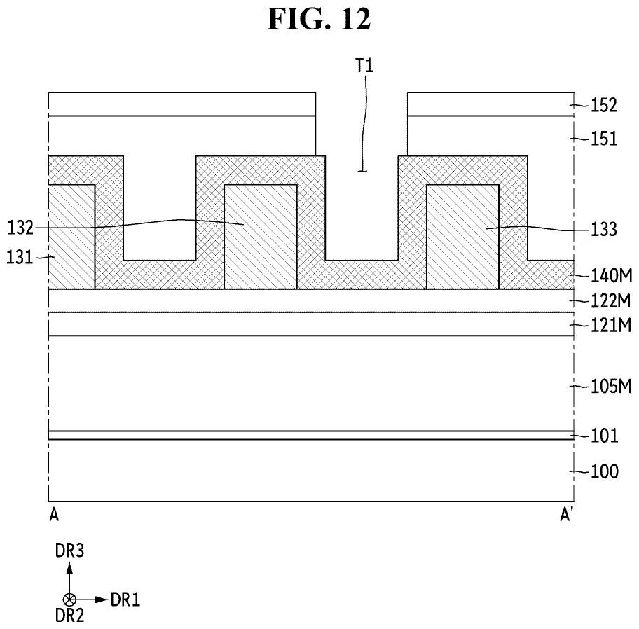

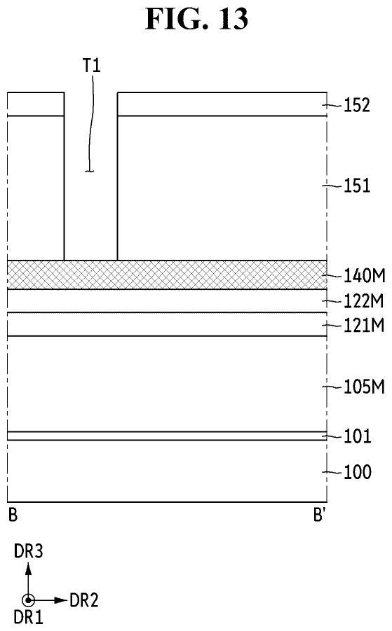

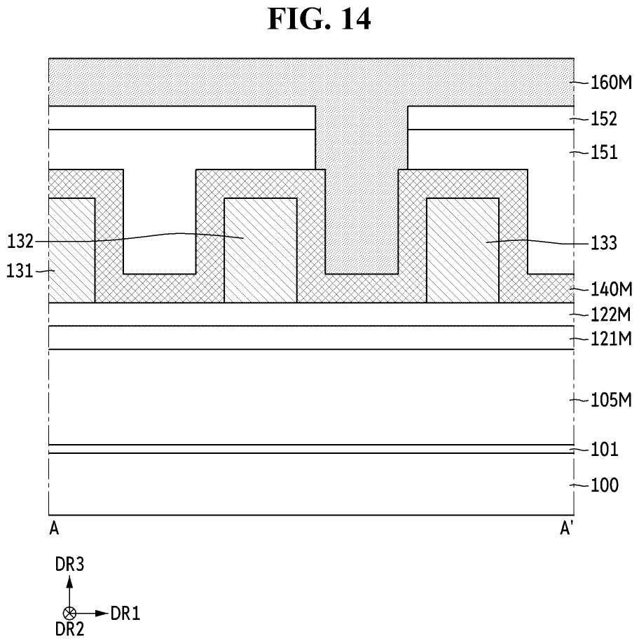

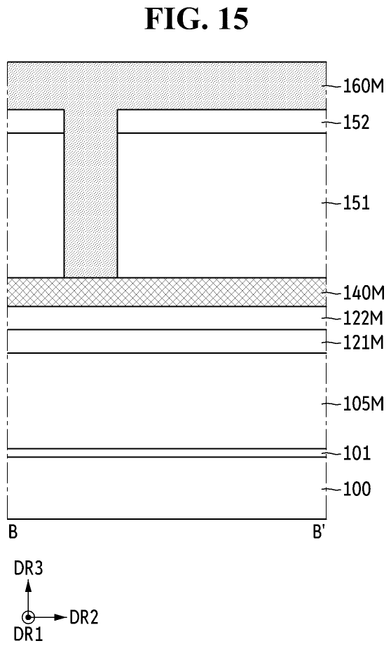

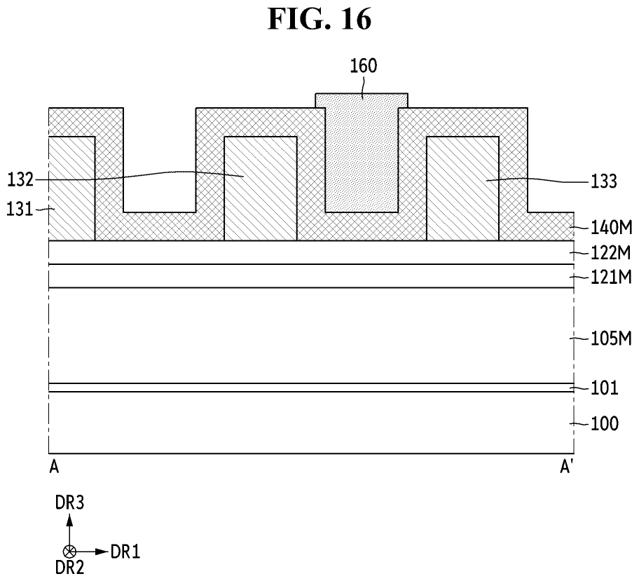

FIGS. 12 and 13 illustrate cross-sectional views in FIGS. 10 and 11, respectively, including a first trench T1 formed in a first photoresist pattern PR1. Referring to FIG. 12 and FIG. 13, each of the first upper mask material layer 151 and the second upper mask material layer 152 may be etched through the first hole pattern HP1 (FIG. 9 to FIG. 11) to form a first trench T1. For example, while the first trench T1 is being formed or after formation of the first trench T1, the first photoresist pattern PR1 (FIG. 9 to FIG. 11) may be etched. For example, a portion of the spacer material layer 140M formed between the second middle mask pattern 132 and the third middle mask pattern 133 may be exposed through the first trench T1. For example, a portion of the spacer material layer 140M formed between the second middle mask pattern 132 and the third middle mask pattern 133 and on the upper surface of the second lower mask material layer 122M may be exposed through the first trench T1. For example, at least a portion of the uppermost surface of the spacer material layer 140M may be exposed through the first trench T1.

Referring to FIG. 14 and FIG. 15, a sacrificial material layer 160M may be formed inside the first trench T1 (FIG. 12 and FIG. 13). For example, the sacrificial material layer 160M may entirely fill the first trench T1 (FIG. 12 and FIG. 13). For example, the sacrificial material layer 160M may also be formed on the upper surface of the second upper mask material layer 152. For example, in a region between the second middle mask pattern 132 and the third middle mask pattern 133, the sacrificial material layer 160M may be in contact with the spacer material layer 140M. For example, the sacrificial material layer 160M may include a different material from that of the spacer material layer 140M. In some example embodiments, the sacrificial material layer 160M may include silicon oxide (SiO₂). In some other example embodiments, the sacrificial material layer 160M may include silicon nitride (SiN). In some example embodiments, the sacrificial material layer 160M may include any other type of material that may be suitable for filling the first trench T1.

Referring to FIG. 16 and FIG. 17, a portion of the sacrificial material layer 160M (FIG. 14 and FIG. 15) may be etched by performing a first etch-back etching process thereon. For example, in the first etch-back etching process, a portion of the sacrificial material layer 160M (FIGS. 14 and 15) formed on the upper surface of the second upper mask material layer 152 may be etched. Moreover, in the first etch-back etching process, a portion of the sacrificial material layer 160M (FIG. 14 and FIG. 15) formed in the first trench T1 (FIG. 12 and FIG. 13) may be etched. After the first etch-back etching process has been completed, the remaining portion of the sacrificial material layer 160M (FIGS. 14 and 15) may be defined as a sacrificial pattern 160. As illustrated in FIG. 16, the sacrificial pattern 160 is formed between the second middle mask pattern 132 and the third middle mask pattern 133, and the sacrificial pattern 160 contacts the spacer material layer 140M.

In some instances, and as illustrated, an uppermost surface of the sacrificial pattern 160 may be higher (in the vertical direction DR3 in FIG. 16) than the uppermost surface of the spacer material layer 140M. For example, at least a portion of the sacrificial pattern 160 may contact the uppermost surface of the spacer material layer 140M. The sacrificial pattern 160 does not overlap (or, is otherwise offset from) each of the second middle mask pattern 132 and the third middle mask pattern 133 in the vertical direction DR3. In some example embodiments, the sacrificial pattern 160 may include a material different from that of the spacer material layer 140M. Subsequently, the first upper mask material layer 151 and the second upper mask material layer 152 may be etched.

FIG. 18 illustrates a layout of an intermediate structure after the operations in FIGS. 9-17. FIG. 19 is the cross-sectional view of the intermediate structure in FIG. 18 taken along line A-A′. FIG. 20 is the cross-sectional view of the intermediate structure in FIG. 18 taken along line B-B′. Referring to FIG. 18 to FIG. 20, a portion of the spacer material layer 140M (FIG. 16 and FIG. 17) may be etched by performing a second etch-back etching process thereon. For example, in the second etch-back etching process, a portion of the upper surface of the second lower mask material layer 122M disposed between the first middle mask pattern 131 and the second middle mask pattern 132 may be exposed. In addition, in the second etch-back etching process, a portion of the upper surface of the second lower mask material layer 122M disposed between the second middle mask pattern 132 and the third middle mask pattern 133 may be exposed. However, a portion of the spacer material layer 140M (FIG. 16 and FIG. 17) formed between the upper surface of the second lower mask material layer 122M and the lower surface of the sacrificial pattern 160 in the first trench T1 is not etched. For example, in the second etch-back etching process, the upper surface of each of the first to third middle mask patterns 131, 132, and 133 may be exposed. Moreover, in the second etch-back etching process, a portion of the sacrificial pattern 160 may be etched.

After the second etch-back etching process has been completed, the remaining portion of the spacer material layer 140M (FIGS. 16 and 17) may be defined as a spacer pattern 140. For example, the spacer pattern 140 may be formed on a sidewall of each of the first to third middle mask patterns 131, 132, and 133. Moreover, the spacer pattern 140 may be formed between the upper surface of the second lower mask material layer 122M and the lower surface of the sacrificial pattern 160. As illustrated in FIG. 19, the upper surface of each of the first to third middle mask patterns 131, 132, and 133, the upper surface of the sacrificial pattern 160, and the upper surface of the spacer pattern 140 are coplanar with each other.

FIG. 21 illustrates a layout of an intermediate structure after the operations in FIGS. 19-21. FIG. 22 is the cross-sectional view of the intermediate structure in FIG. 21 taken along line A-A′. FIG. 23 is the cross-sectional view of the intermediate structure in FIG. 21 taken along line B-B′. Referring to FIG. 21 to FIG. 23, a third upper mask material layer 153 may be formed on the upper surface of the second lower mask material layer 122M and to cover each of the first to third middle mask patterns 131, 132, and 133, the spacer pattern 140, and the sacrificial pattern 160. An upper surface of the third upper mask material layer 153 may be planar. In some example embodiments, the third upper mask material layer 153 may include SOH (spin-on hardmask). Subsequently, a fourth upper mask material layer 154 may be formed on an upper surface of the third upper mask material layer 153. For example, the fourth upper mask material layer 154 may be formed conformally. In some example embodiments, the fourth upper mask material layer 154 may include silicon oxynitride (SiON) or silicon nitride (SiN). Subsequently, a second photoresist pattern PR2 may be formed on an upper surface of the fourth upper mask material layer 154. For example, the second photoresist pattern PR2 may be formed such that a portion of the upper surface of the fourth upper mask material layer 154 overlapping each of the first to third middle mask patterns 131, 132, and 133 in the vertical direction DR3 may be exposed.

Referring to FIG. 24 to FIG. 26, using the second photoresist pattern PR2 (FIG. 21 to FIG. 23) as a mask, each of the fourth upper mask material layer 154 (FIG. 21 to FIG. 23), the third upper mask material layer 153 (FIG. 21 to FIG. 23), and the first to third middle mask pattern 131, 132, and 133 (FIG. 21 to FIG. 23) may be etched. For example, while this etching process is performed (or alternatively, after the etching process has been performed), the second photoresist pattern PR2 (FIG. 21 to FIG. 23) may be etched (or stripped). Subsequently, the fourth upper mask material layer 154 (FIG. 21 to FIG. 23) and the third upper mask material layer 153 (FIG. 21 to FIG. 23) may be etched.

Next, using the spacer pattern 140 (FIG. 21 to FIG. 23) and the sacrificial pattern 160 (FIG. 21 to FIG. 23) as a mask, the first lower mask material layer 121M (FIG. 21 to FIG. 23) and the second lower mask material layer 122M (FIG. 21 to FIG. 23) may be etched. After this etching process has been completed, the remaining portion of the first lower mask material layer 121M (FIG. 21 to FIG. 23) may be defined as a first lower mask pattern 121, and the remaining portion of the second lower mask material layer 122M (FIG. 21 to FIG. 23) may be defined as a second lower mask pattern 122. The etching may expose a portion of an upper surface of the insulating material layer 105M between the first lower mask patterns 121. Subsequently, the spacer pattern 140 (FIG. 21 to FIG. 23) and the sacrificial pattern 160 (FIG. 21 to FIG. 23) may be etched.

Referring to FIG. 27 and FIG. 28, the insulating material layer 105M (FIG. 24 to FIG. 26) may be etched using the first lower mask pattern 121 and the second lower mask pattern 122 as a mask. After this etching process has been completed, the remaining portion of the insulating material layer 105M (FIG. 24 to FIG. 26) may be defined as an insulating pattern 105 and the etching stop layer 101 may be exposed in a region between the insulating patterns 105.

Referring to FIG. 1 to FIG. 3, a plurality of wiring patterns may be respectively formed between the insulating patterns 105 and on the upper surface of the etching stop layer 101. For example, the plurality of wiring patterns may include the first to seventh wiring patterns 111 to 117.

In some example embodiments, a pitch in the second horizontal direction DR2 between the fourth wiring pattern 114 and the fifth wiring pattern 115 may be equal to a width in the second horizontal direction DR2 of the sacrificial pattern 160 (FIG. 21 to FIG. 23). The semiconductor device as shown in FIG. 1 to FIG. 3 may thus be fabricated using the method described above.

In the method for fabricating the semiconductor device according to some example embodiments, the sacrificial pattern 160 may be formed in a region to isolate the fourth wiring pattern 114 and the fifth wiring pattern 115 from each other using the first photoresist pattern PR1 including the first hole pattern HP1, and the first and second lower mask patterns 121 and 122 may be formed using the spacer pattern 140 formed on the lower surface of the sacrificial pattern 160 and the sidewall of each of the first to third middle mask patterns 131, 132, and 133 as the mask, and the insulating pattern 105 may be formed using the first and second lower mask patterns 121 and 122 as the mask, and each of the first to seventh wiring patterns 111 to 117 may be formed between adjacent ones of the insulating patterns 105.

Thus, the method for fabricating the semiconductor device, according to some example embodiments of the inventive concepts, as described above may reduce etching of an end or edge of each of the first to seventh wiring patterns 111 to 117. For example, the method for fabricating the semiconductor device according to some example embodiments of the inventive concept may limit each of the end of the fourth wiring pattern 114 facing the fifth wiring pattern 115 and the end of the fifth wiring pattern 115 facing the fourth wiring pattern 114 from being formed having a curved or rounded (or otherwise chamfered or beveled) edges. Thus, the method for fabricating the semiconductor device according to some example embodiments of the inventive concepts may improve the reliability of each of the first to seventh wiring patterns 111 to 117, and thereby the reliability and performance of the circuit or system that incorporates such a semiconductor device.

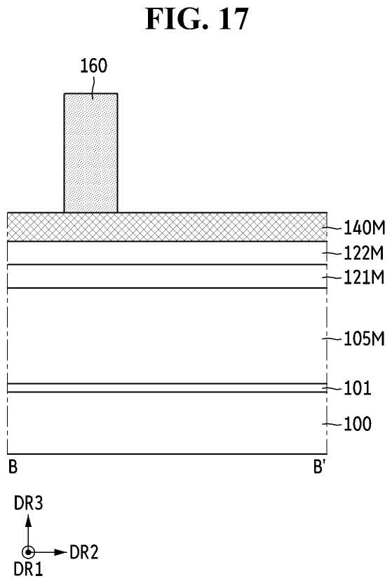

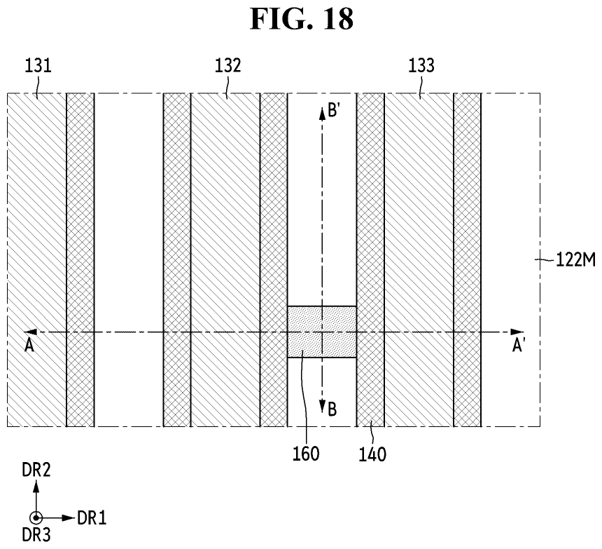

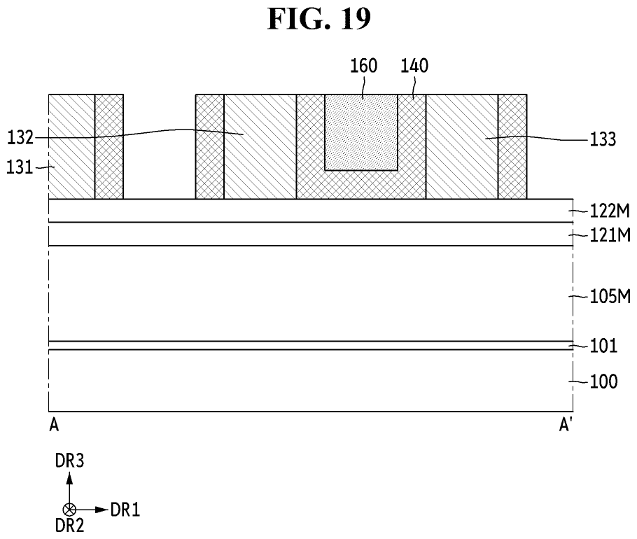

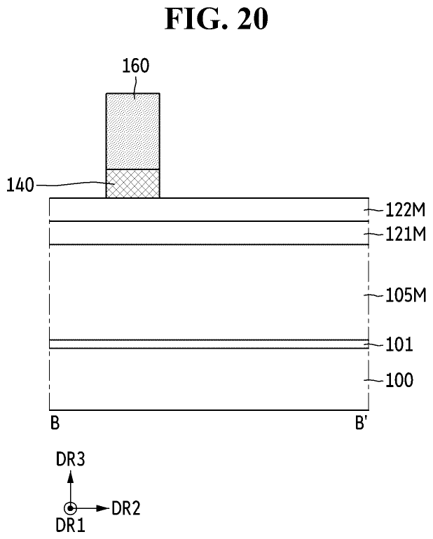

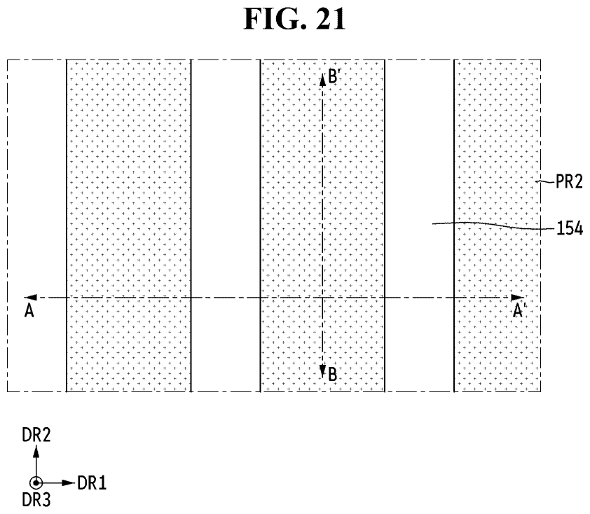

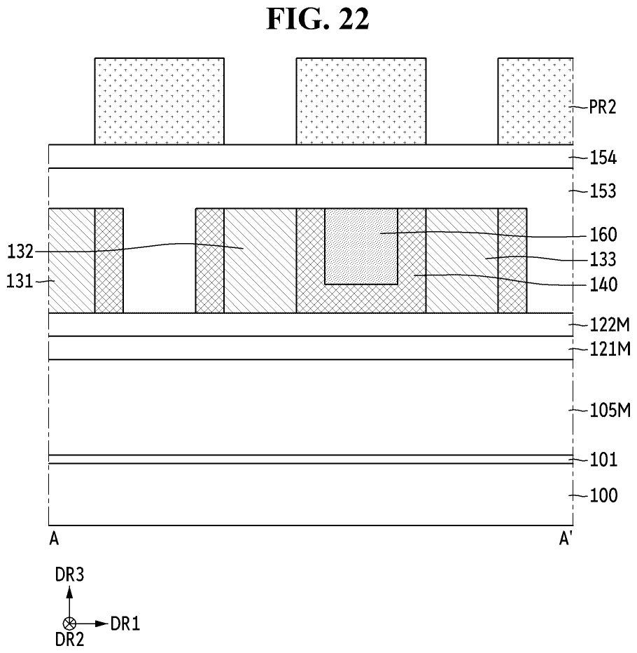

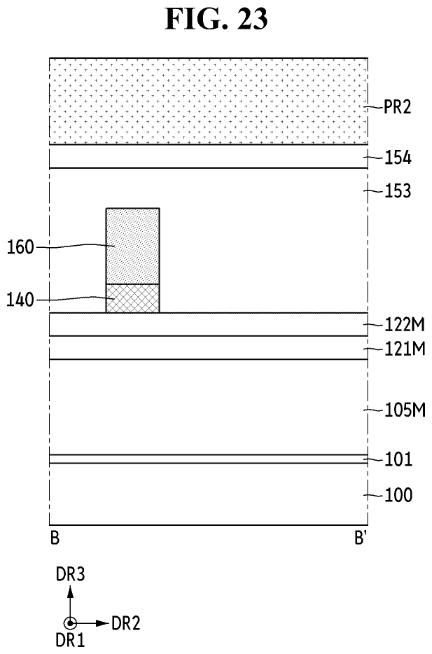

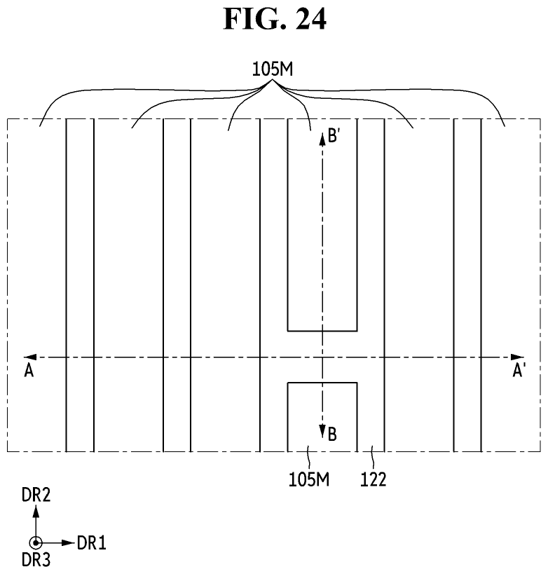

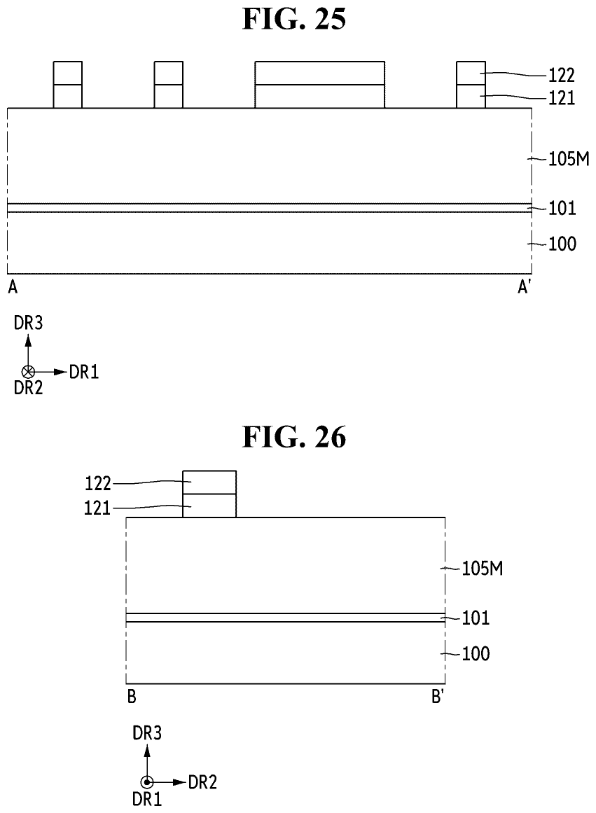

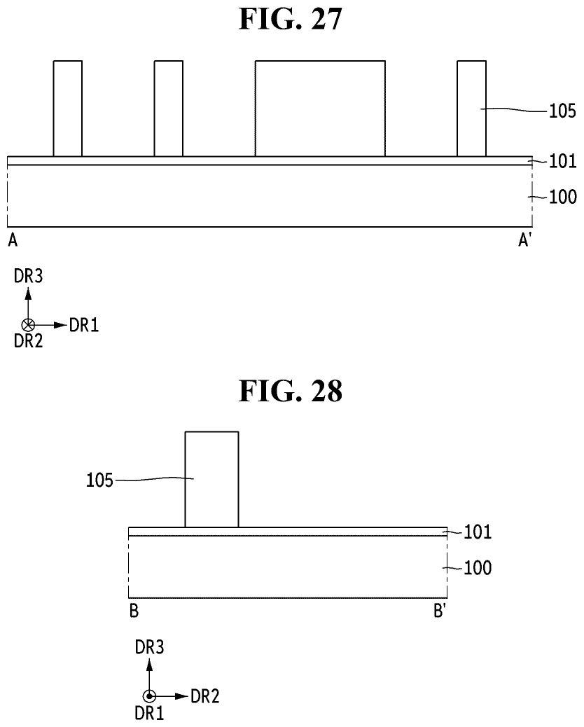

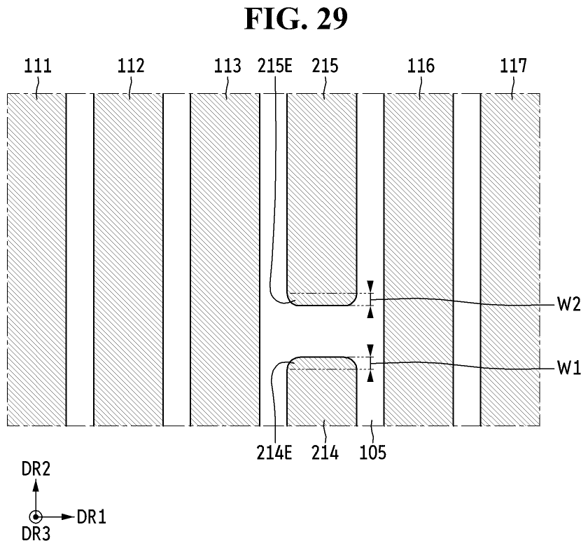

Hereinafter, a semiconductor device according to other example embodiments of inventive concepts is described with reference to FIG. 29.

FIG. 29 is a layout of an example semiconductor device. Referring to FIG. 29, each of an end 214E of the fourth wiring pattern 214 and an end 215E of the fifth wiring pattern 215 may include curved or rounded edges.

A portion of the end 214E of the fourth wiring pattern 214 facing the fifth wiring pattern 215 may include a curved or rounded edges. Moreover, a portion of the end 215E of the fifth wiring pattern 215 facing the fourth wiring pattern 214 may include a curved or rounded edges. For example, each of a width W1 in the second horizontal direction DR2 of the end 214E of the fourth wiring pattern 214 including the curved edge and a width W2 in the second horizontal direction DR2 of the end 215E of the fifth wiring pattern 215 including the curved edge may be 7 nm or less. For example, when each of the width W1 in the second horizontal direction DR2 of the end 214E of the fourth wiring pattern 214 and the width W2 in the second horizontal direction DR2 of the end 215E of the fifth wiring pattern 215 is around 0, the semiconductor device as shown in FIG. 1 to FIG. 3 may be obtained.

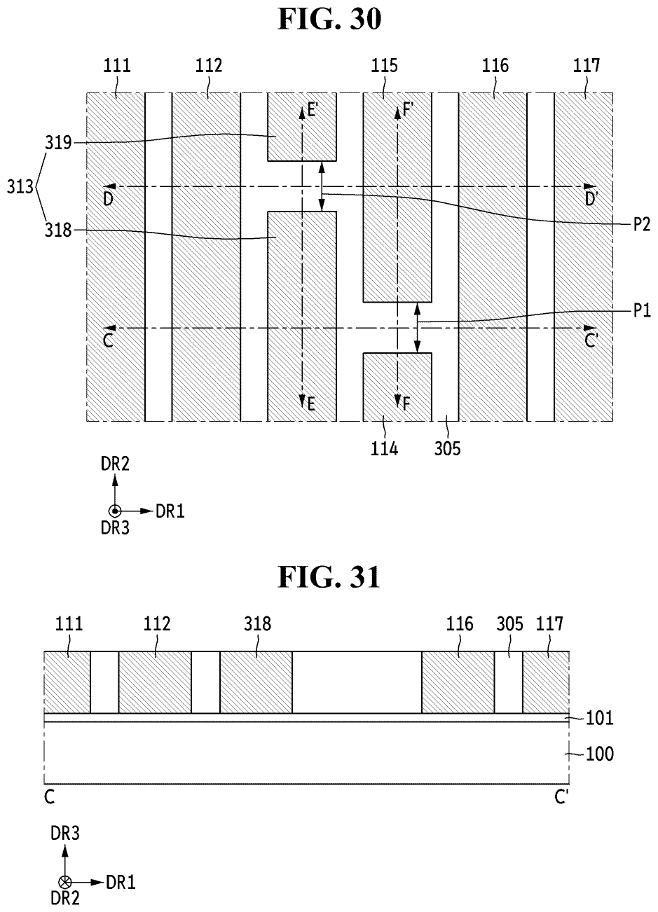

Hereinafter, a semiconductor device according to some example embodiments of the inventive concepts is described with reference to FIG. 30 to FIG. 34.

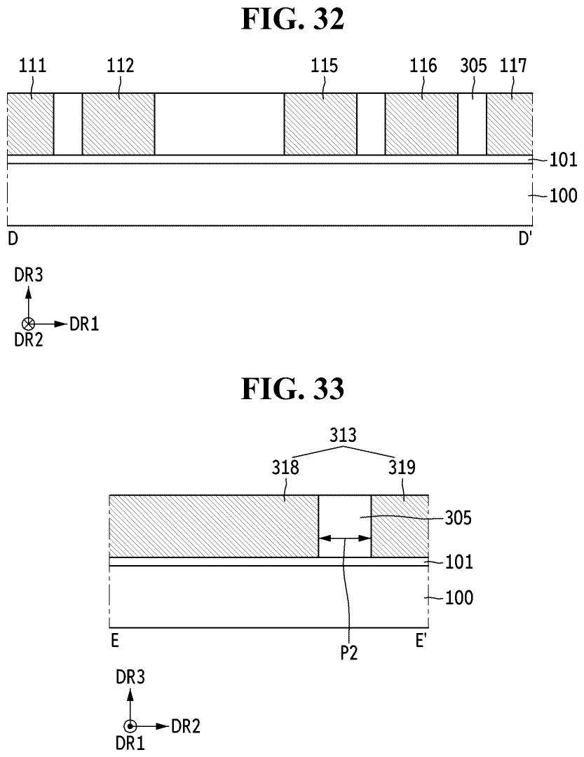

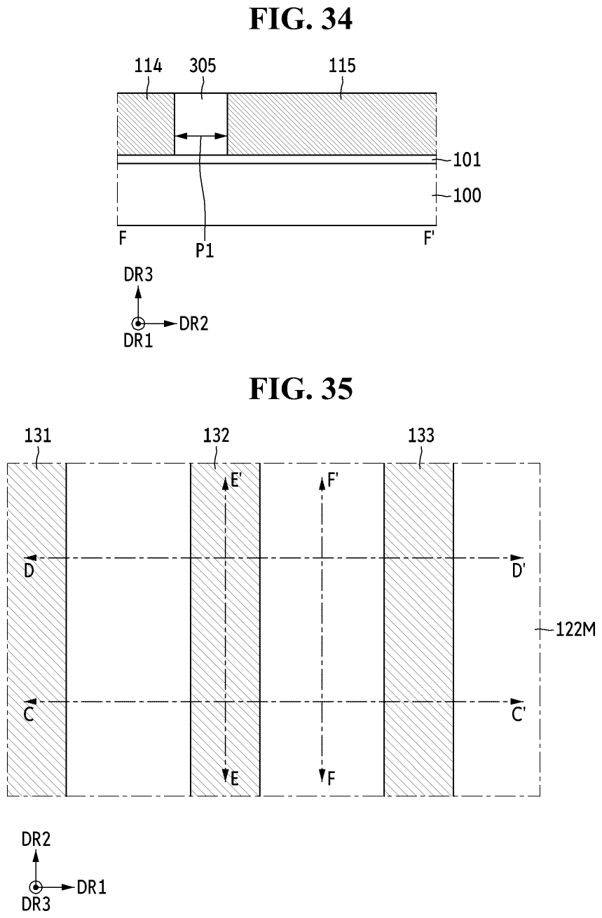

FIG. 30 is a layout illustrating a semiconductor device according to some example embodiments of the inventive concepts. FIG. 31 is a cross-sectional view along a line C-C′ in FIG. 30. FIG. 32 is a cross-sectional view along a line D-D′ in FIG. 30. FIG. 33 is a cross-sectional view along a line E-E′ in FIG. 30. FIG. 34 is a cross-sectional view cut a line F-F′ in FIG. 30.

Referring to FIG. 30 to FIG. 34, the semiconductor device includes an eighth wiring pattern 318 and a ninth wiring pattern 319 (collectively referred to as third wiring pattern 313) and which are spaced from each other in the second horizontal direction DR2.

For example, the eighth wiring pattern 318 may be disposed between the second wiring pattern 112 and each of the fourth and fifth wiring patterns 114 and 115. The ninth wiring pattern 319 may be disposed between the second wiring pattern 112 and the fifth wiring pattern 115. The ninth wiring pattern 319 may be spaced (or separated) from the eighth wiring pattern 318 in the second horizontal direction DR2. For example, a pitch P1 in the second horizontal direction DR2 between the fourth wiring pattern 114 and the fifth wiring pattern 115 may be equal to a pitch P2 in the second horizontal direction DR2 between the eighth wiring pattern 318 and the ninth wiring pattern 319.

For example, the insulating pattern 305 may surround the sidewall of each of the first to seventh wiring patterns 111, 112, 313, 114, 115, 116 and 117 while being disposed on the upper surface of the etching stop layer 101. For instance, the insulating pattern 305 may surround a sidewall of each of the eighth wiring pattern 318 and the ninth wiring pattern 319. For example, the insulating pattern 305 may be disposed between the fourth wiring pattern 114 and the fifth wiring pattern 115. Moreover, the insulating pattern 305 may be disposed between the eighth wiring pattern 318 and the ninth wiring pattern 319.

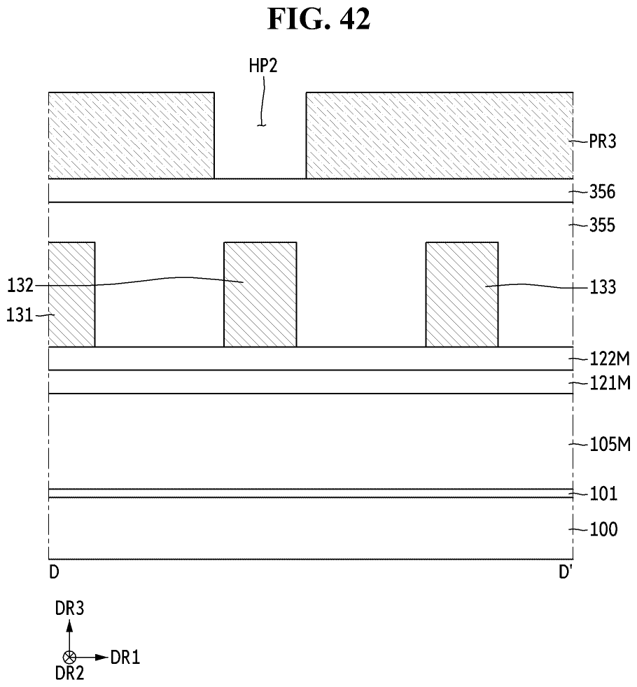

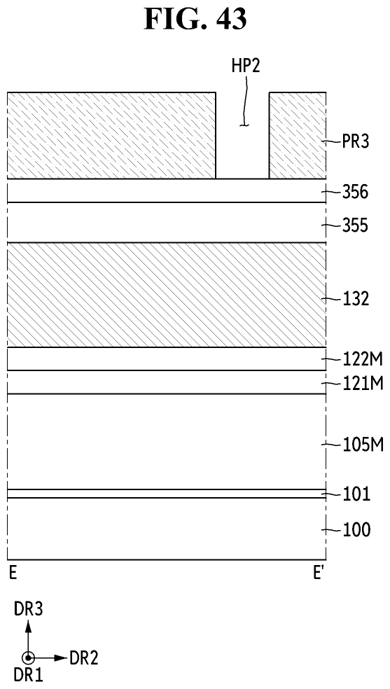

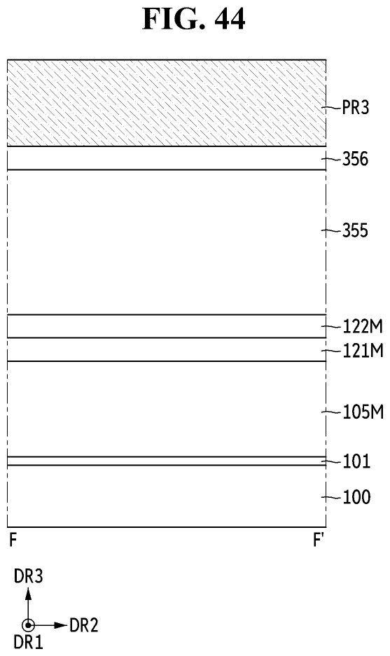

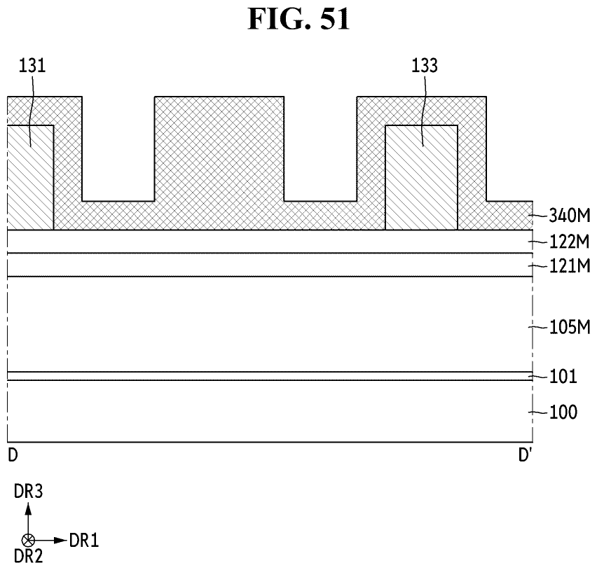

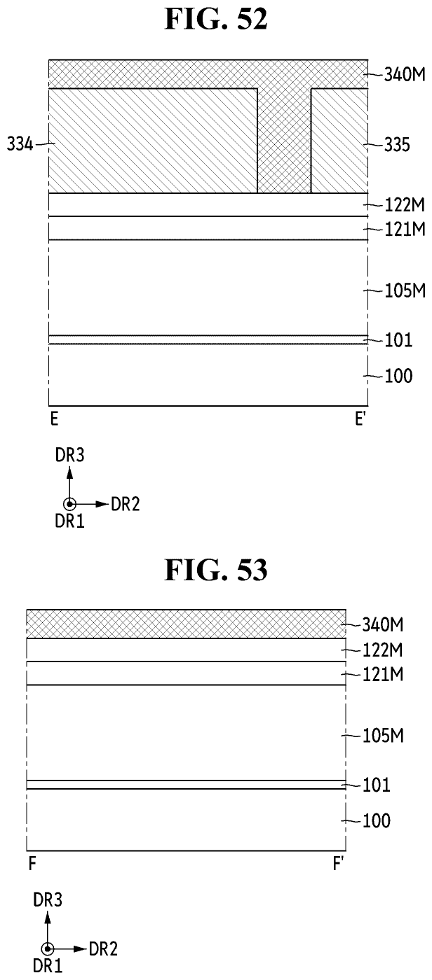

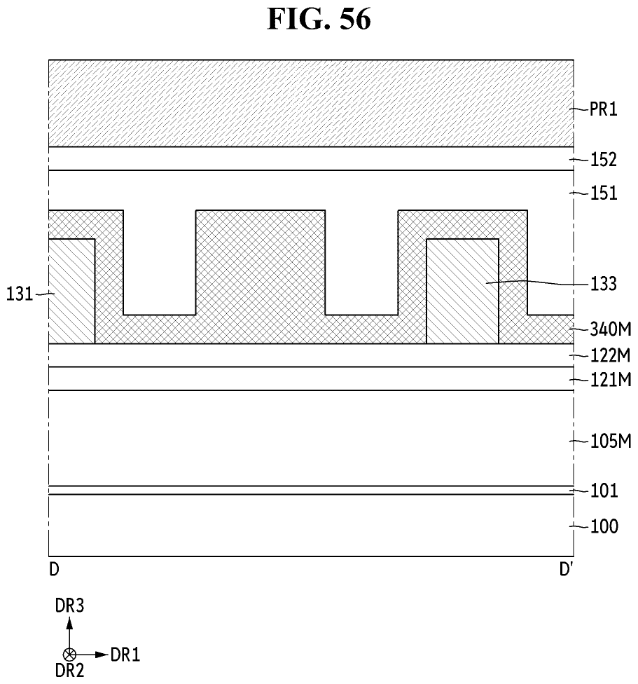

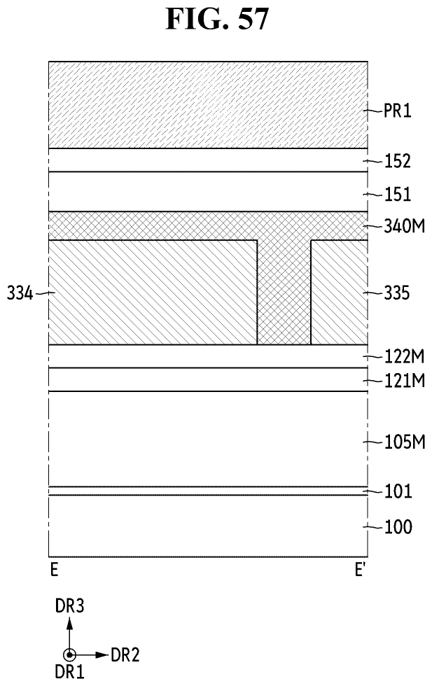

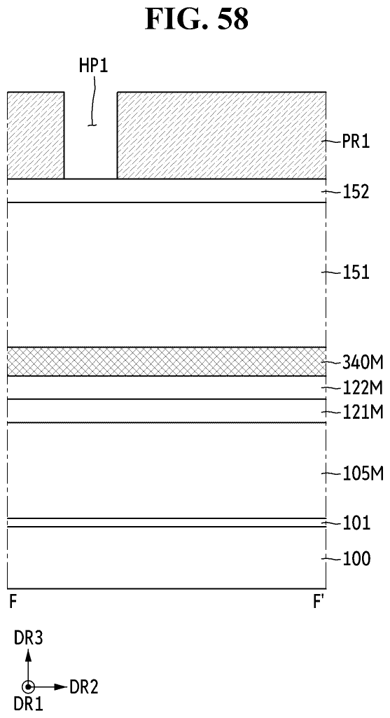

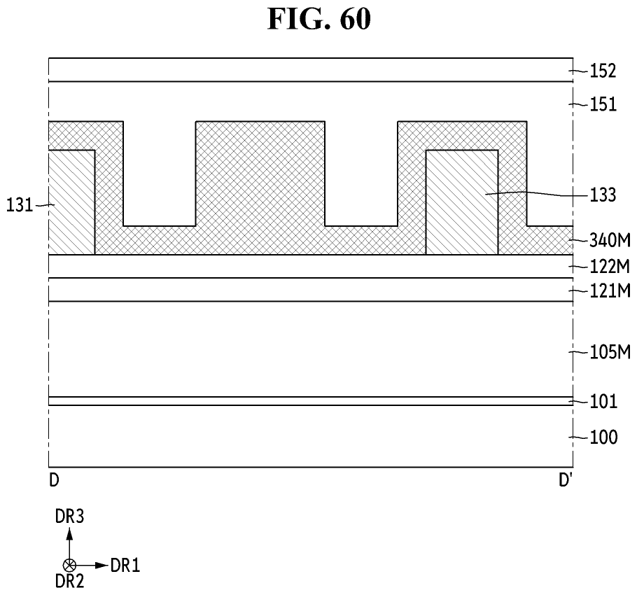

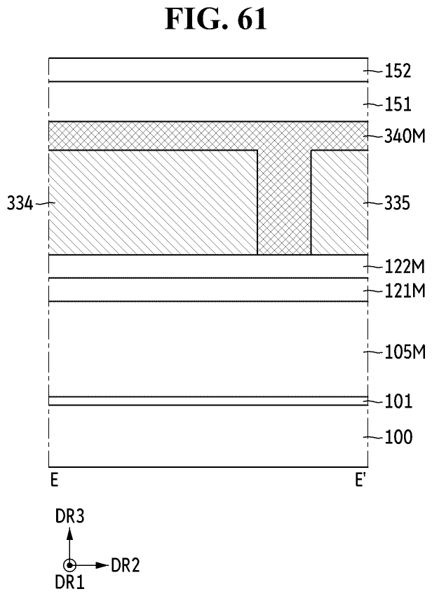

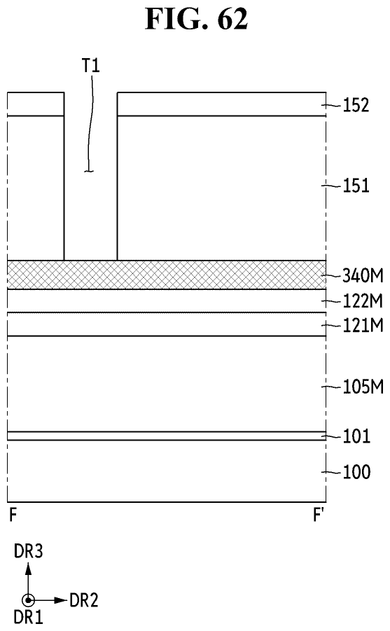

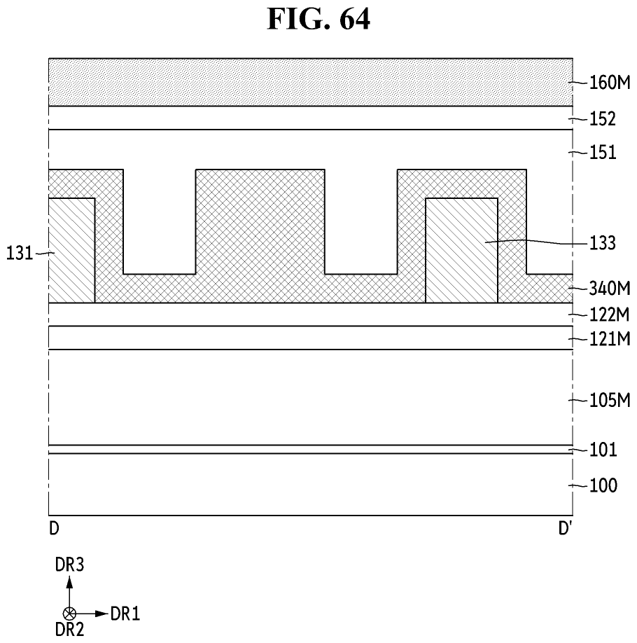

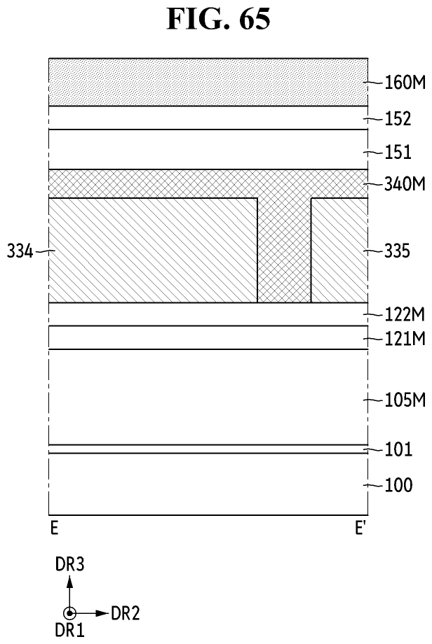

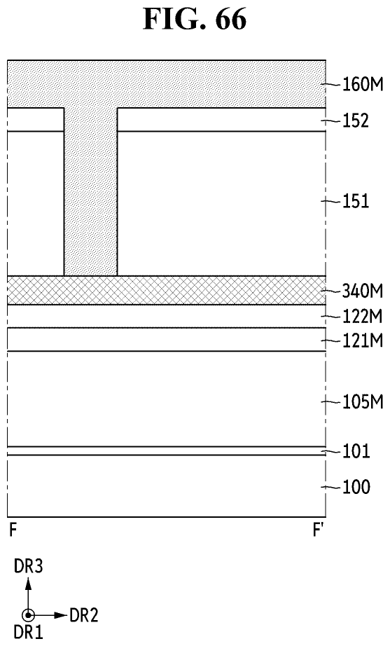

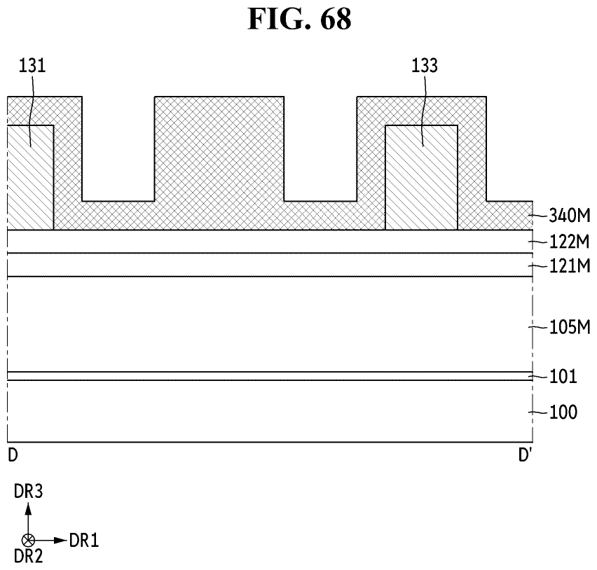

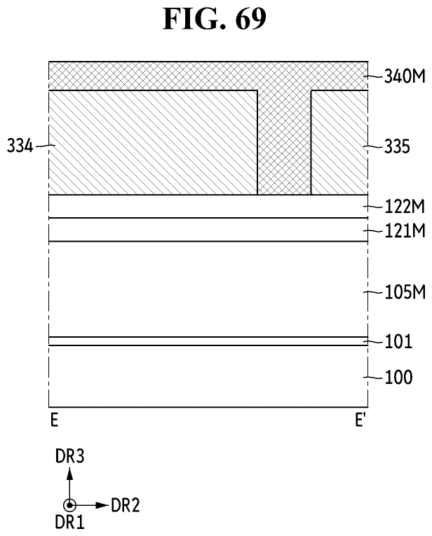

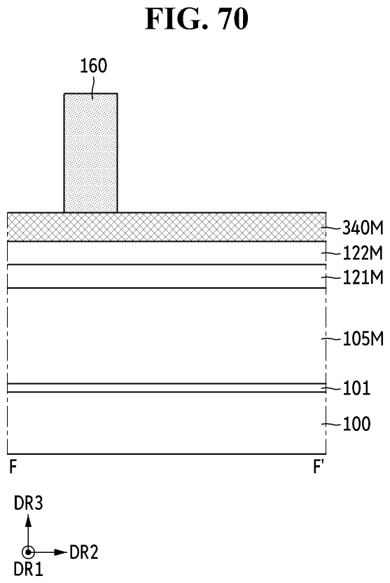

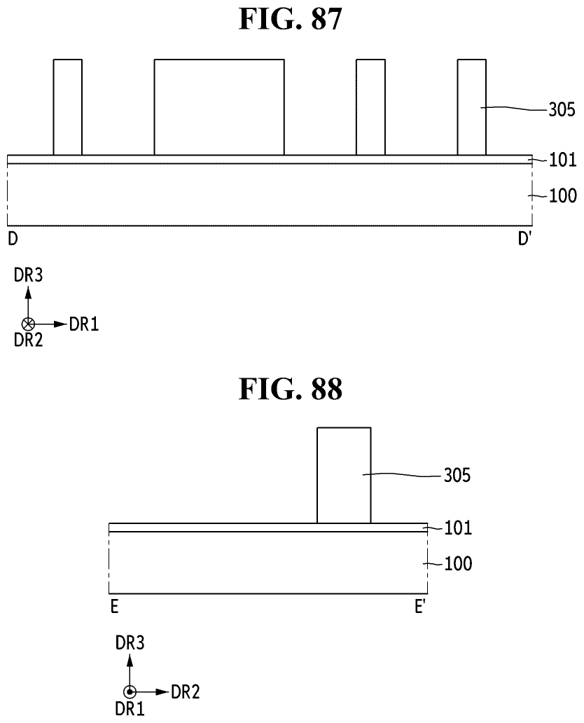

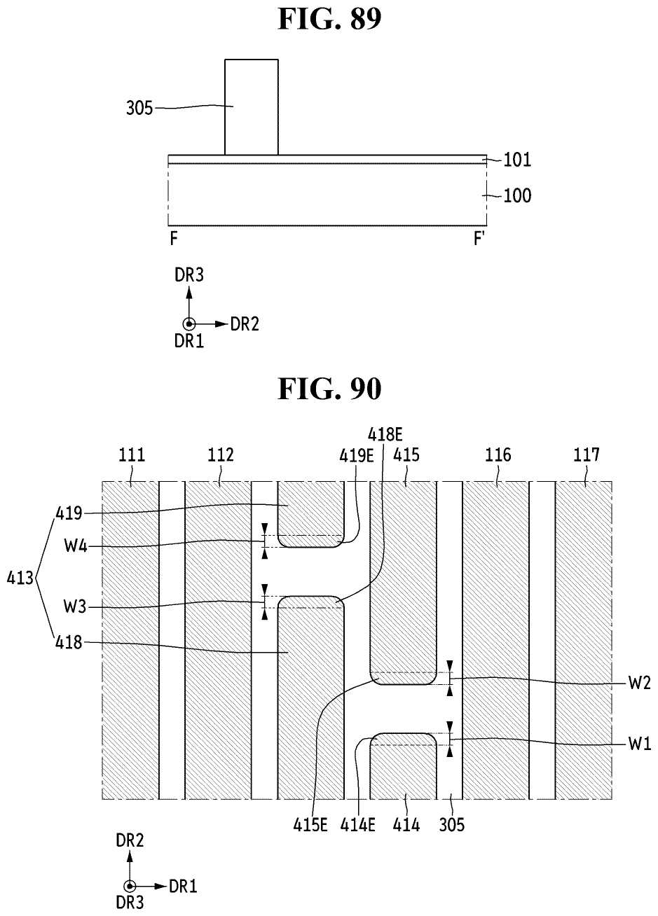

FIG. 35 to FIG. 89 are directed to a method for fabricating a semiconductor device according to some example embodiments of the inventive concepts. The method discussed with reference to FIGS. 35-89 may be substantially similar to the method discussed with reference to FIG. 4 to FIG. 28, and therefore may be best understood with reference thereto, where like numerals represent like elements not described again in detail.

FIG. 35 to FIG. 89 illustrate intermediate structures corresponding to intermediate operations of a method for fabricating a semiconductor device according to some example embodiments of the inventive concepts.

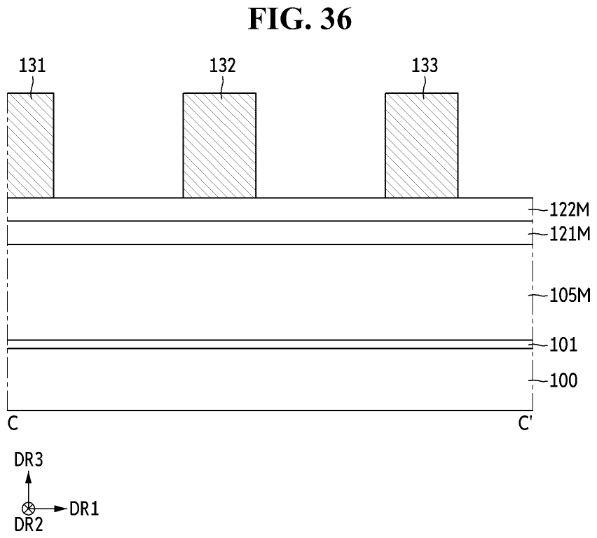

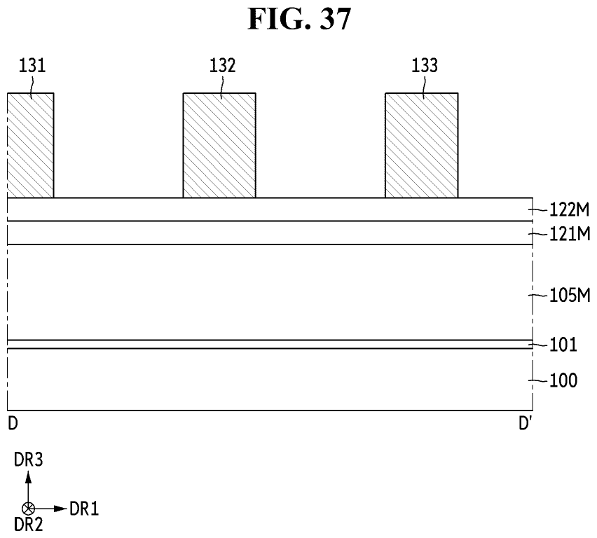

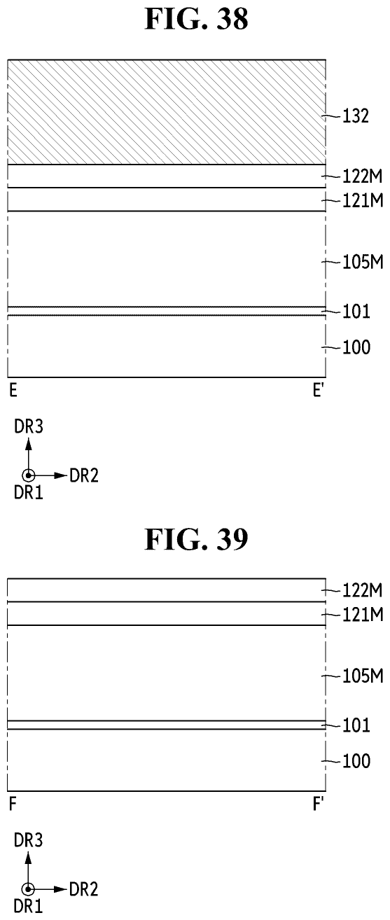

FIG. 35 illustrates a layout of an intermediate structure. FIG. 36 is the cross-sectional view of the intermediate structure in FIG. 35 taken along line C-C′. FIG. 37 is the cross-sectional view of the intermediate structure in FIG. 35 taken along line D-D′. FIG. 38 is the cross-sectional view of the intermediate structure in FIG. 35 taken along line E-E′. FIG. 39 is the cross-sectional view of the intermediate structure in FIG. 35 taken along line F-F′. Referring to FIG. 35 to FIG. 39, the etching stop layer 101, the insulating material layer 105M, the first lower mask material layer 121M, and the second lower mask material layer 122M may be formed sequentially on the upper (or top) surface of the substrate 100. Subsequently, the first to third middle mask patterns 131, 132 and 133 may be formed on the upper surface of the second lower mask material layer 122M. The second middle mask pattern 132 may be spaced from the first middle mask pattern 131 in the first horizontal direction DR1. The third middle mask pattern 133 may be spaced from the second middle mask pattern 132 in the first horizontal direction DR1.

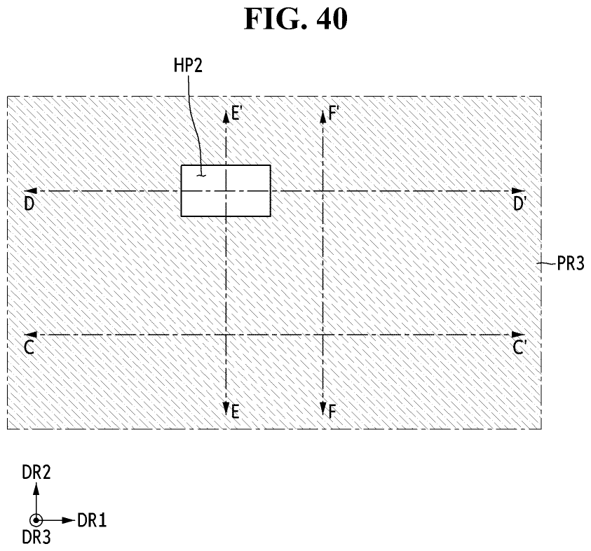

Referring to FIG. 40 to FIG. 44, a fifth upper mask material layer 355 and a sixth upper mask material layer 356 may be formed sequentially on the upper (or top) surface of the second lower mask material layer 122M, and each of the first to third middle mask patterns 131, 132 and 133. For example, the fifth upper mask material layer 355 may be in contact with the upper (or top) surface of the second lower mask material layer 122M, and the sidewall and the upper (or top) surface of each of the first to third middle mask patterns 131, 132, and 133. For example, an upper surface of the fifth upper mask material layer 355 may be formed to be flat. For example, the fifth upper mask material layer 355 may include SOH (spin-on hardmask). The sixth upper mask material layer 356 may contact the upper (or top) surface of the fifth upper mask material layer 355. For example, the sixth upper mask material layer 356 may be formed conformally. For example, the sixth upper mask material layer 356 may include silicon oxynitride SiON, silicon nitride (SiN), a combination thereof, or the like.

Subsequently, a third photoresist pattern PR3 including a second hole pattern HP2 may be formed on an upper surface of the sixth upper mask material layer 356. In some example embodiments, the second hole pattern HP2 may extend through the third photoresist pattern PR3 in the vertical direction DR3. For example, the second hole pattern HP2 may be formed on the upper surface of the second middle mask pattern 132. A portion of the upper surface of the sixth upper mask material layer 356 may be exposed through the second hole pattern HP2. In some example embodiments, a width in the first horizontal direction DR1 of the second hole pattern HP2 may be larger than a width in the first horizontal direction DR1 of the second middle mask pattern 132.

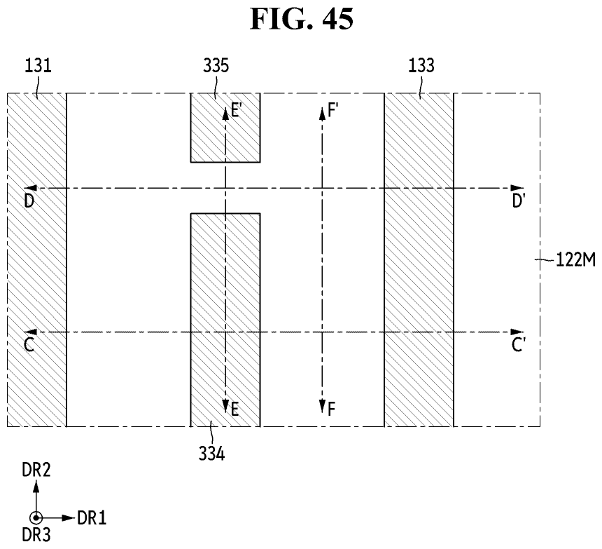

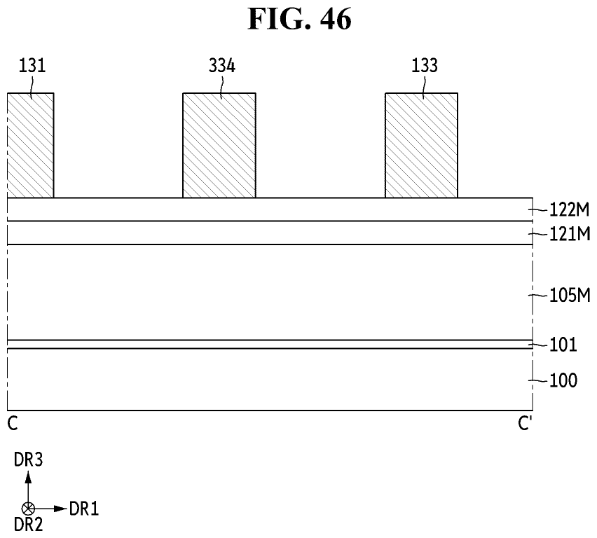

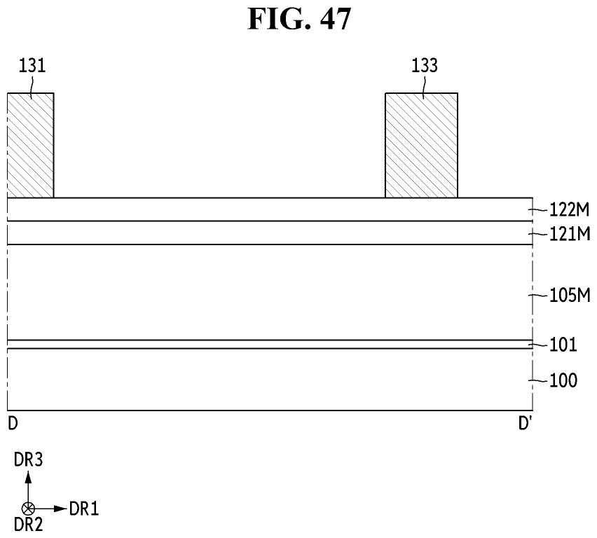

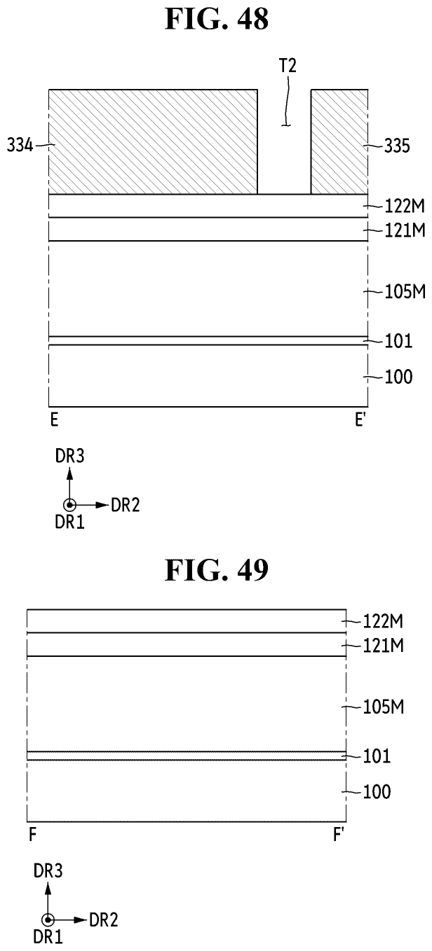

FIG. 45 illustrates a layout of an intermediate structure formed after the operations in FIGS. 40-44. FIG. 46 is the cross-sectional view of the intermediate structure in FIG. 45 taken along line C-C′. FIG. 47 is the cross-sectional view of the intermediate structure in FIG. 45 taken along line D-D′. FIG. 48 is the cross-sectional view of the intermediate structure in FIG. 45 taken along line E-E′. FIG. 49 is the cross-sectional view of the intermediate structure in FIG. 45 taken along line F-F′. Referring to FIG. 45 to FIG. 49, each of the fifth upper mask material layer 355 (FIG. 40 to FIG. 44), the sixth upper mask material layer 356 (FIG. 40 to FIG. 44), and the second middle mask pattern 132 (FIG. 40 to FIG. 44) is etched through the second hole pattern HP2 to form a second trench T2. For example, while the second trench T2 is being formed (or, alternatively, after forming the second trench T2), the second photoresist pattern PR2 (FIG. 40 to FIG. 44) may be etched or stripped. After this etching (or stripping) process has been completed, the second middle mask pattern 132 (FIG. 40 to FIG. 44) is divided into the fourth middle mask pattern 334 and the fifth middle mask pattern 335 via the second trench T2 such that the fourth middle mask pattern 334 and the fifth middle mask pattern 335 are spaced from each other in horizontal direction DR2. The second middle mask pattern 132 (FIG. 40 to FIG. 44) may include the fourth middle mask pattern 334 and the fifth middle mask pattern 335 spaced from each other in the second horizontal direction DR2. The fifth middle mask pattern 335 may be spaced from the fourth middle mask pattern 334 in the second horizontal direction DR2. For example, as illustrated in FIG. 48, a portion of the upper surface of the second lower mask material layer 122M may be exposed through the second trench T2. Subsequently, the fifth upper mask material layer 355 (FIG. 40 to FIG. 44) and the sixth upper mask material layer 356 (FIG. 40 to FIG. 44) may be etched.

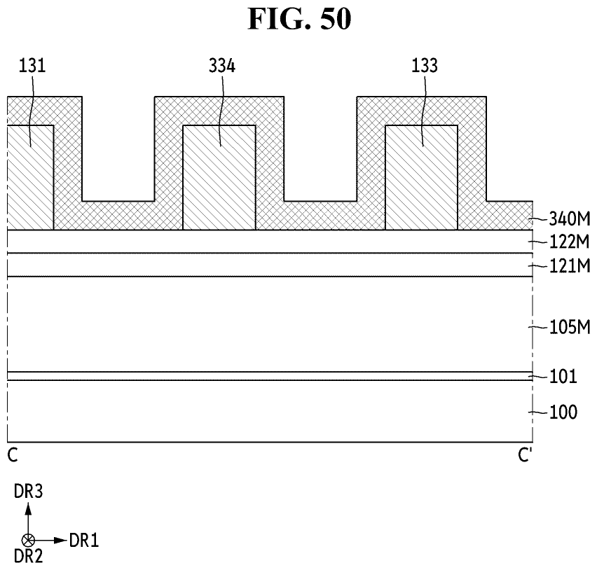

Referring to FIG. 50 to FIG. 53, a spacer material layer 340M may be formed on a sidewall and an upper surface of each of the first, and third to fifth middle mask patterns 131, 133, 334, and 335. For example, a spacer material layer 340M may fill the second trench T2 (FIG. 48). The spacer material layer 340M may be also formed on the upper surface of the second lower mask material layer 122M. For example, the spacer material layer 340M may be conformally formed. The spacer material layer 340M may include a material different from that of each of the first, and third to fifth middle mask patterns 131, 133, 334, and 335. For example, the spacer material layer 340M may include titanium oxide (TiO₂). In some example embodiments, the spacer material layer 340M may include titanium nitride (TiN), amorphous carbon layer (ACL), silicon oxide (SiO₂), combination thereof or the like.

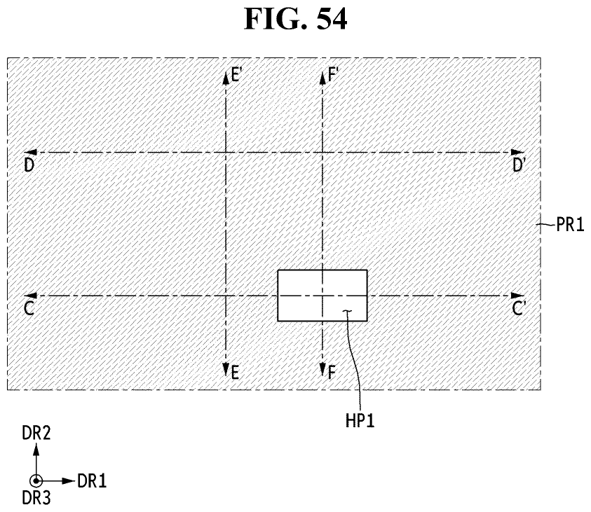

FIG. 54 illustrates a layout of an intermediate structure formed after the above operations. FIG. 46 is the cross-sectional view of the intermediate structure in FIG. 45 taken along line C-C′. FIG. 47 is the cross-sectional view of the intermediate structure in FIG. 45 taken along line D-D′. FIG. 48 is the cross-sectional view of the intermediate structure in FIG. 45 taken along line E-E′. FIG. 49 is the cross-sectional view of the intermediate structure in FIG. 45 taken along line F-F′. Referring to FIG. 54 to FIG. 58, the first upper mask material layer 151 and the second upper mask material layer 152 may be formed sequentially on an upper surface of the spacer material layer 340M. Subsequently, the first photoresist pattern PR1 including the first hole pattern HP1 may be formed on the upper surface of the second upper mask material layer 152. For example, the first hole pattern HP1 may be formed between the fourth middle mask pattern 334 and the third middle mask pattern 133. A portion of the upper surface of the second upper mask material layer 152 between the fourth middle mask pattern 334 and the third middle mask pattern 133 may be exposed through the first hole pattern HP1. For example, the width in the first horizontal direction DR1 of the first hole pattern HP1 may be smaller than the pitch in the first horizontal direction DR1 between the fourth middle mask pattern 334 and the third middle mask pattern 133. In some example embodiments, the first hole pattern HP1 does not overlap each of the fourth middle mask pattern 334 and the third middle mask pattern 133 in the vertical direction DR3.

In some example embodiments, the first hole pattern HP1 does not overlap with the second hole pattern HP2 (FIG. 40) in each of the first and second horizontal directions DR1 and DR2. For example, the width in the second horizontal direction DR2 of the first hole pattern HP1 may be equal to the width in the second horizontal direction DR2 of the second hole pattern HP2 (FIG. 40).

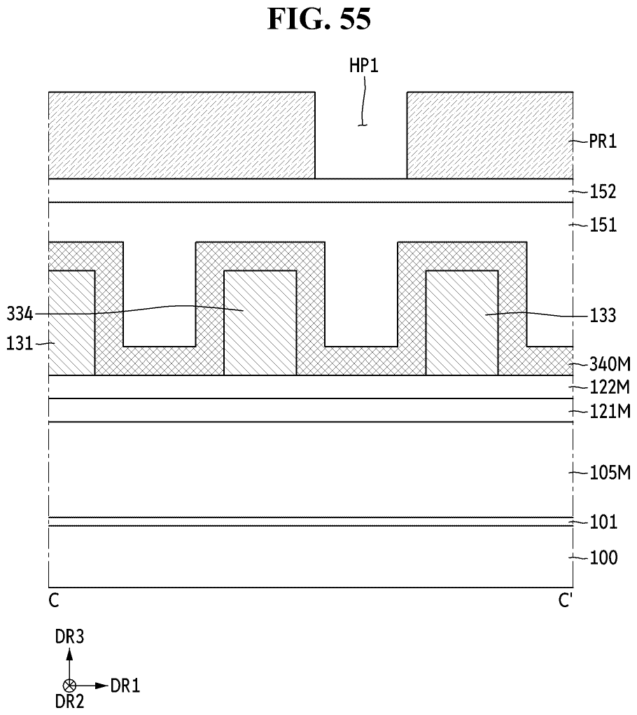

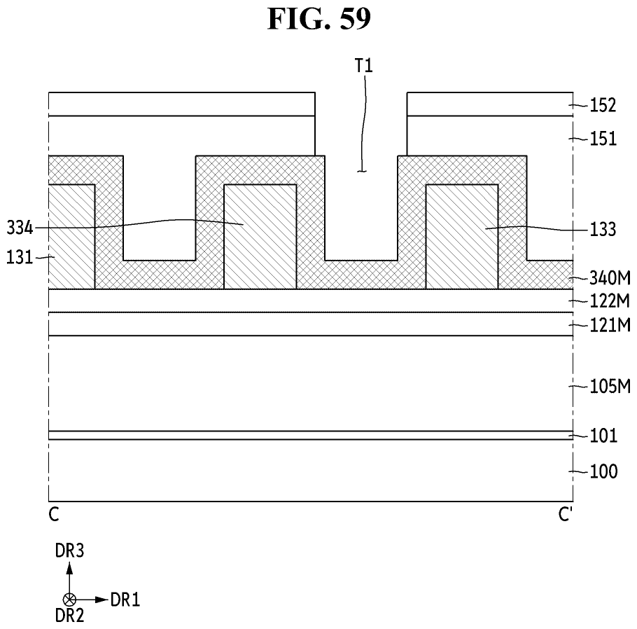

Referring to FIG. 59 to FIG. 62, with continued reference to FIGS. 55-58, each of the first upper mask material layer 151 and the second upper mask material layer 152 may be etched through the first hole pattern HP1 (FIG. 55 to FIG. 58) to form the first trench T1. For example, while the first trench T1 is being formed (or alternatively, after the first trench T1 is formed), the first photoresist pattern PR1 (FIG. 55 to FIG. 58) may be etched (or stripped). For example, a portion of the spacer material layer 340M formed between the fourth middle mask pattern 334 and the third middle mask pattern 133 may be exposed through the first trench T1. For example, a portion of the spacer material layer 340M formed between the fourth middle mask pattern 334 and the third middle mask pattern 133 and on the upper surface of the second lower mask material layer 122M may be exposed through the first trench T1. For example, at least a portion of the upper surface of the spacer material layer 340M may be exposed through the first trench T1.

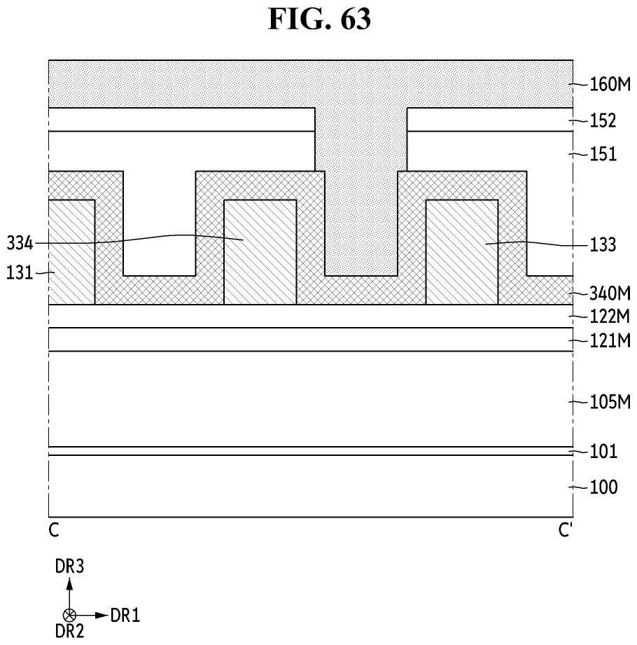

Referring to FIG. 63 to FIG. 66, with continued reference to FIGS. 59-62, a sacrificial material layer 160M may be formed inside the first trench T1 (FIG. 59 to FIG. 62). For example, the sacrificial material layer 160M may also be formed on the upper surface of the second upper mask material layer 152. For example, a portion of the sacrificial material layer 160M between the fourth middle mask pattern 334 and the third middle mask pattern 133 may contact the spacer material layer 340M. In some example embodiments, the sacrificial material layer 160M may include a different material from that of the spacer material layer 340M.

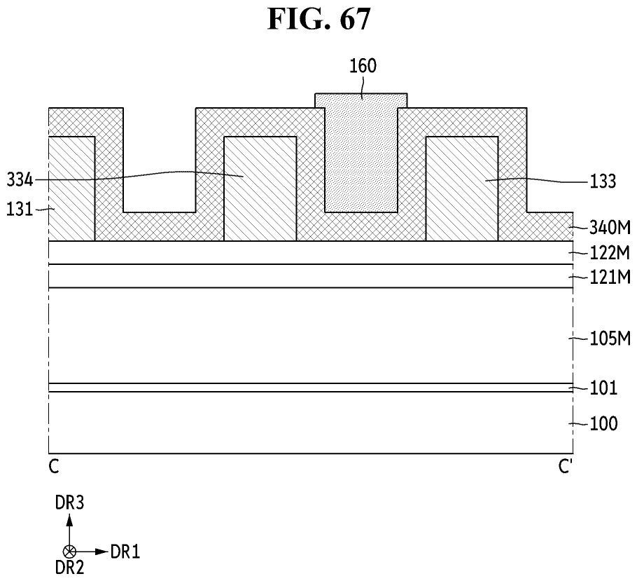

Referring to FIG. 67 to FIG. 70, with continued reference to FIGS. 63-66, a portion of the sacrificial material layer 160M (FIG. 63 to FIG. 66) may be etched by performing a first etch-back etching process thereon. For example, in the first etch-back etching process, the sacrificial material layer 160M (FIG. 63 to FIG. 66) formed on the upper surface of the second upper mask material layer 152 may be etched. In addition, in the first etch-back etching process, a portion of the sacrificial material layer 160M (FIG. 63 to FIG. 66) formed in the first trench T1 (FIG. 59 to FIG. 62) may be etched. After the first etch-back etching process has been completed, the remaining portion of the sacrificial material layer 160M (FIG. 63 to FIG. 66) may be defined as a sacrificial pattern 160. For example, the sacrificial pattern 160 does not overlap each of the fourth middle mask pattern 334 and the third middle mask pattern 133 in the vertical direction DR3. Subsequently, the first upper mask material layer 151 and the second upper mask material layer 152 may be etched.

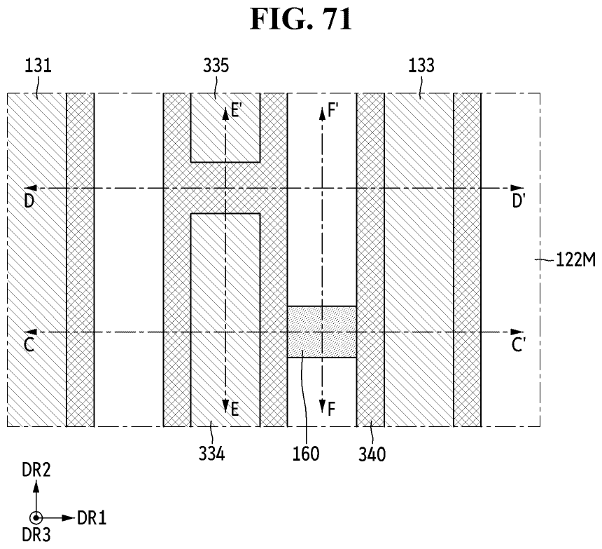

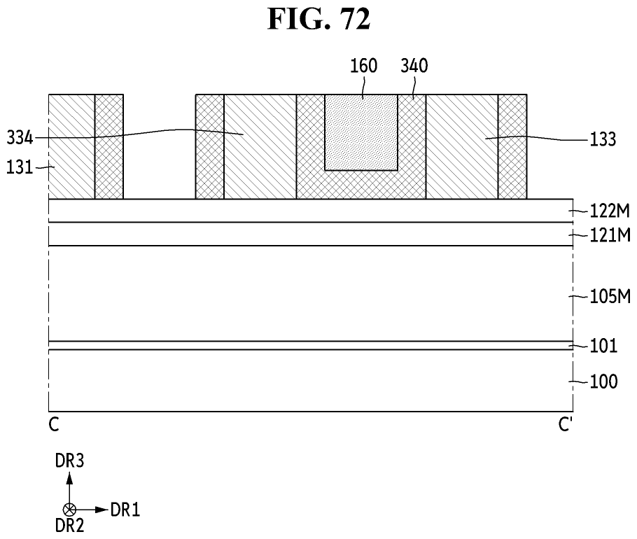

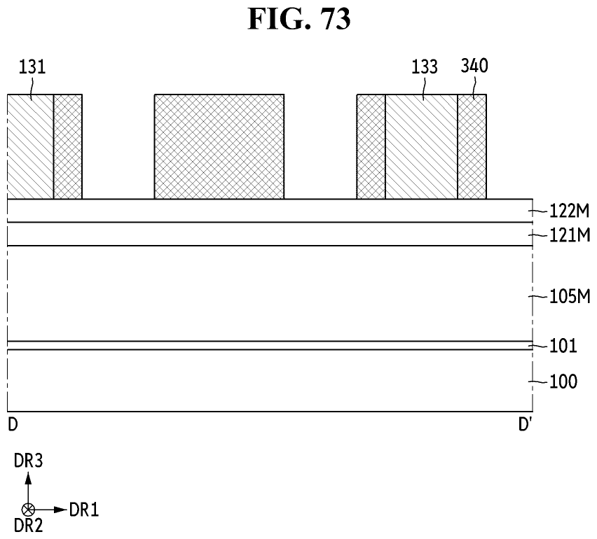

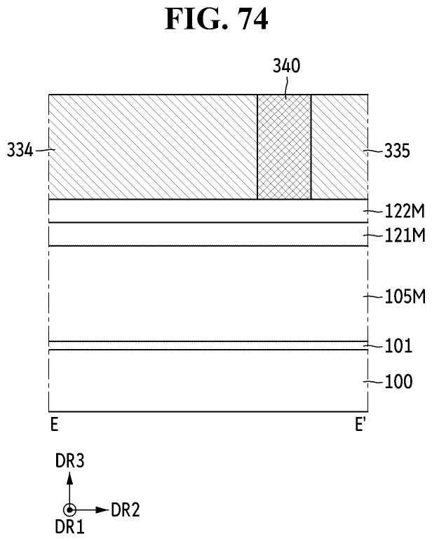

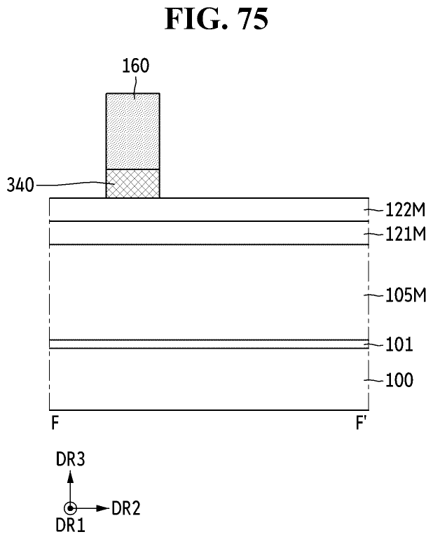

FIG. 71 illustrates a layout of an intermediate structure formed after the above operations. FIG. 72 is the cross-sectional view of the intermediate structure in FIG. 71 taken along line C-C′. FIG. 73 is the cross-sectional view of the intermediate structure in FIG. 71 taken along line D-D′. FIG. 74 is the cross-sectional view of the intermediate structure in FIG. 71 taken along line E-E′. FIG. 75 is the cross-sectional view of the intermediate structure in FIG. 71 taken along line F-F′. Referring to FIG. 71 to FIG. 75, a portion of the spacer material layer 340M (FIG. 67 to FIG. 70) may be etched by performing a second etch-back etching process thereon. For example, in the second etch-back etching process, a portion of the upper surface of the second lower mask material layer 122M between the first middle mask pattern 131 and the fourth middle mask pattern 334 may be exposed. In addition, in the second etch-back etching process, a portion of the upper surface of the second lower mask material layer 122M between the fourth middle mask pattern 334 and the third middle mask pattern 133 may be exposed. However, a portion of the spacer material layer 340M (FIG. 67 to FIG. 70) formed between the upper surface of the second lower mask material layer 122M and the lower surface of the sacrificial pattern 160 may not be etched. For example, in the second etch-back etching process, an upper surface of each of the first, third to fifth middle mask patterns 131, 133, 334, and 335 may be exposed. In the second etch-back etching process, a portion of the sacrificial pattern 160 may also be etched. After the second etch-back etching process has been completed, the remaining portion of the spacer material layer 340M (FIG. 67 to FIG. 70) may be defined as the spacer pattern 340.

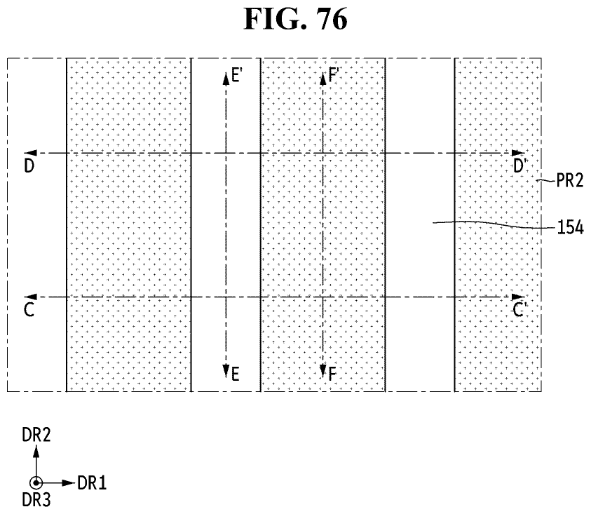

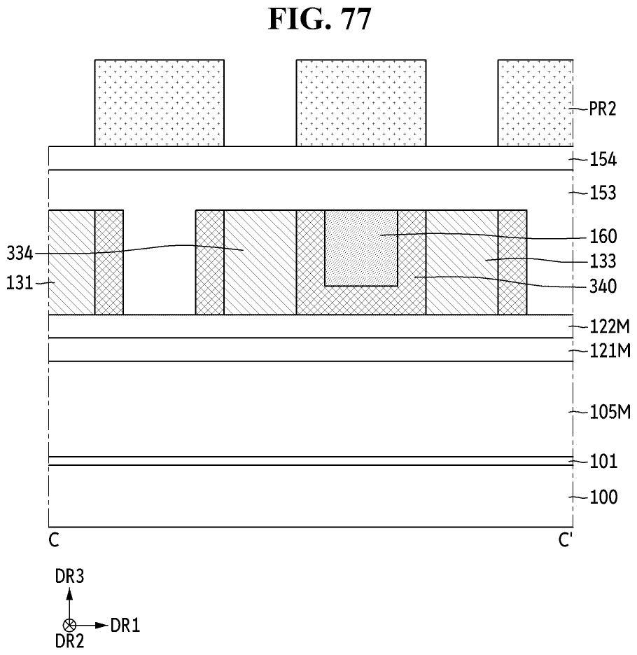

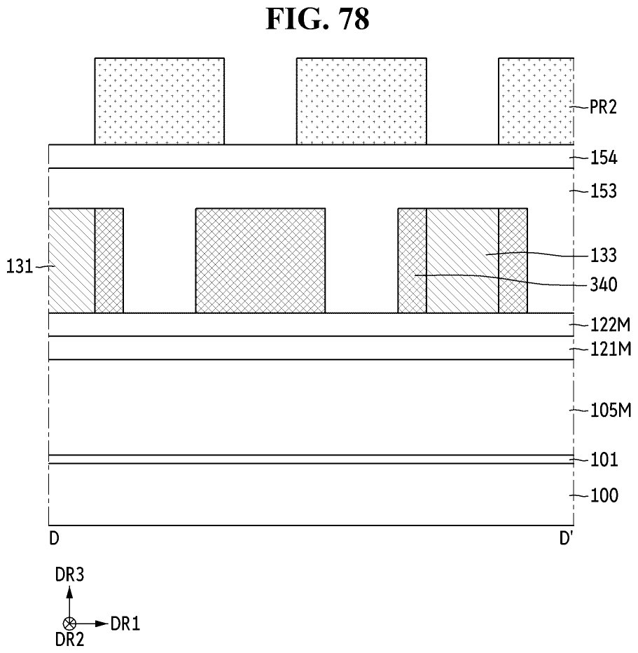

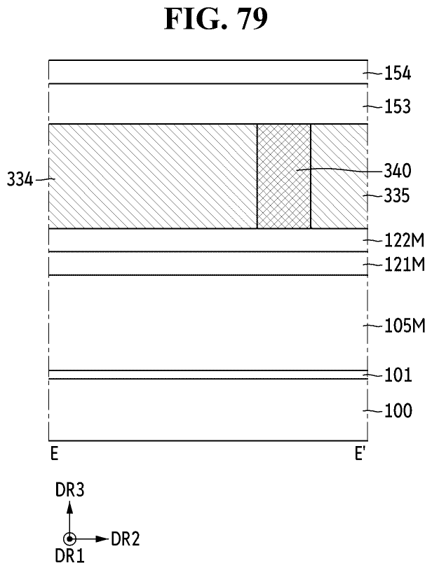

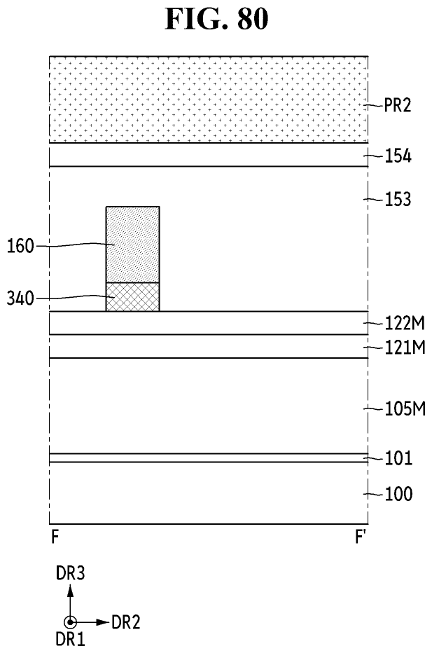

FIG. 76 illustrates a layout of an intermediate structure formed after the above operations. FIG. 77 is the cross-sectional view of the intermediate structure in FIG. 76 taken along line C-C′. FIG. 78 is the cross-sectional view of the intermediate structure in FIG. 76 taken along line D-D′. FIG. 79 is the cross-sectional view of the intermediate structure in FIG. 76 taken along line E-E′. FIG. 80 is the cross-sectional view of the intermediate structure in FIG. 76 taken along line F-F′. Referring to FIG. 76 to FIG. 80, the third upper mask material layer 153 may be formed on the upper surface of the second lower mask material layer 122M to cover each of the first, and third to fifth middle mask pattern 131, 133, 334, and 335, the spacer pattern 340, and the sacrificial patterns 160. Subsequently, the fourth upper mask material layer 154 may be formed on the upper surface of the third upper mask material layer 153. Subsequently, the second photoresist pattern PR2 may be formed on the upper surface of the fourth upper mask material layer 154. For example, the second photoresist pattern PR2 may be formed such that a portion of the upper surface of the fourth upper mask material layer 154 that overlaps each of the first, and third to fifth middle mask patterns 131, 133, 334, and 335 in the vertical direction DR3 may be exposed.

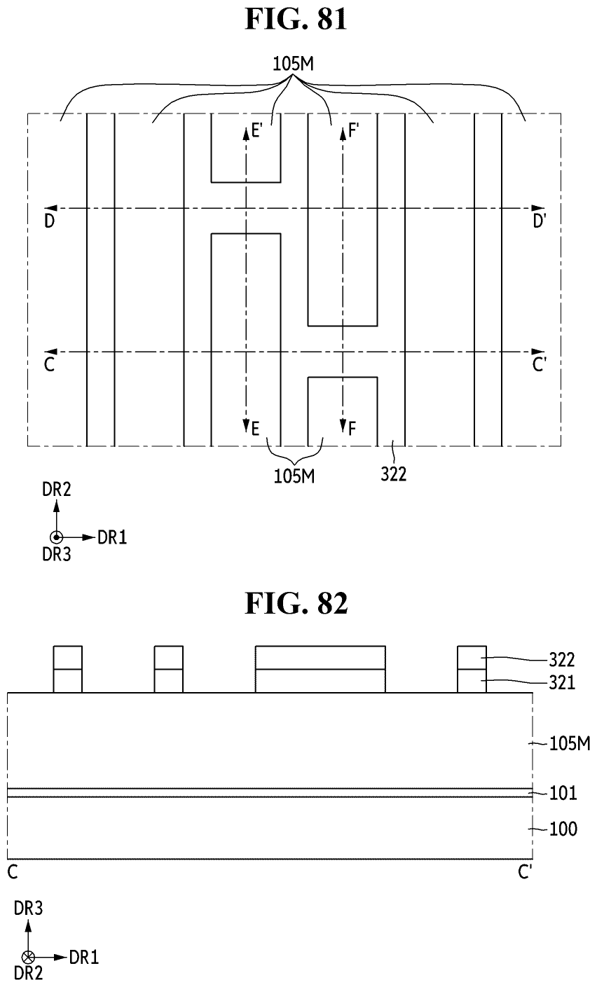

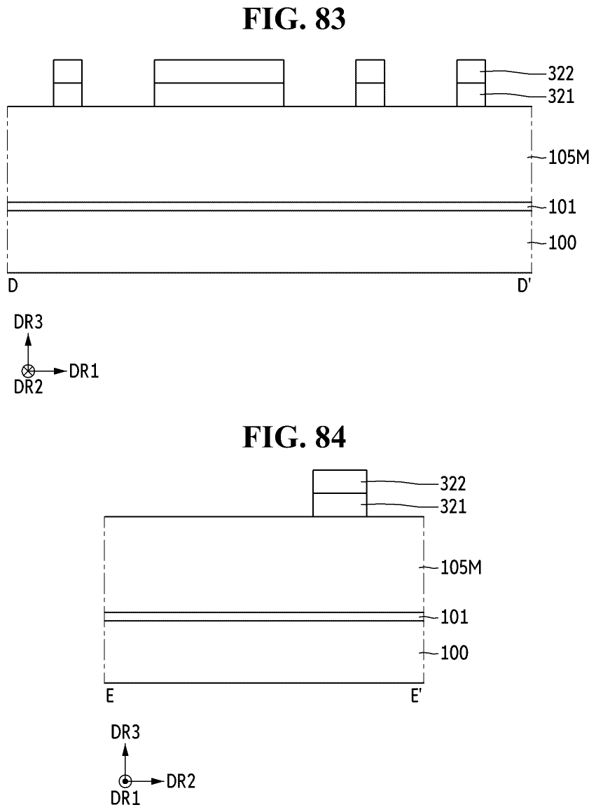

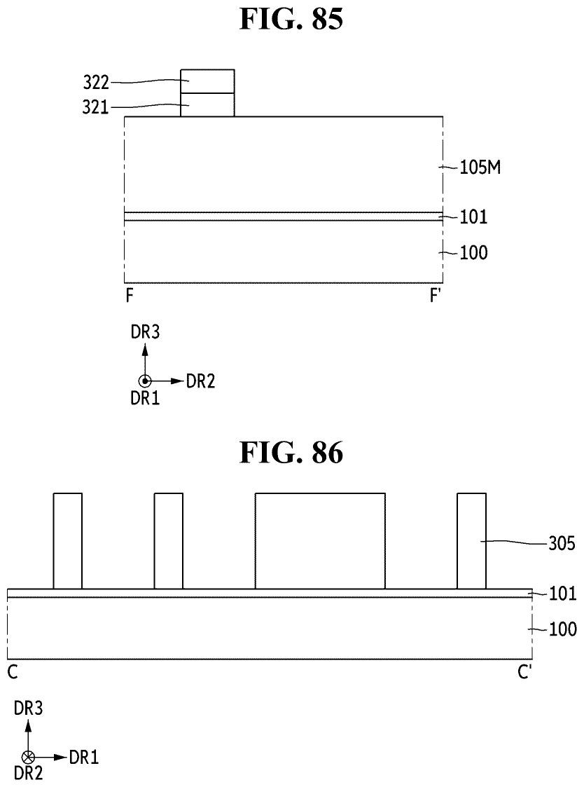

FIG. 81 illustrates a layout of an intermediate structure formed after the above operations. FIG. 82 is the cross-sectional view of the intermediate structure in FIG. 81 taken along line C-C′. FIG. 83 is the cross-sectional view of the intermediate structure in FIG. 81 taken along line D-D′. FIG. 84 is the cross-sectional view of the intermediate structure in FIG. 81 taken along line E-E′. FIG. 85 is the cross-sectional view of the intermediate structure in FIG. 81 taken along line F-F′. Referring to FIG. 81 to FIG. 85, using the second photoresist pattern PR2 (FIG. 76 to FIG. 80) as a mask, each of the fourth upper mask material layer 154 (FIG. 76 to FIG. 80), the third upper mask material layer 153 (FIG. 76 to FIG. 80) and the first, and third to fifth middle mask patterns 131, 133, 334, and 335 (FIG. 76 to FIG. 80) may be etched. For example, while this etching process is performed (or alternatively, after the etching is performed), the second photoresist pattern PR2 (FIG. 76 to FIG. 80) may be etched (or stripped). Subsequently, the fourth upper mask material layer 154 (FIG. 76 to FIG. 80) and the third upper mask material layer 153 (FIG. 76 to FIG. 80) may be etched.

Next, using the spacer pattern 340 (FIG. 76 to FIG. 80) and the sacrificial pattern 160 (FIG. 76 to FIG. 80) as a mask, the first lower mask material layer 121M (FIG. 76 to FIG. 80) and the second lower mask material layer 122M (FIG. 76 to FIG. 80) may be etched. After this etching process has been completed, the remaining portion of the first lower mask material layer 121M (FIG. 76 to FIG. 80) may be defined as the first lower mask pattern 321, and the remaining portion of the second lower mask material layer 122M (FIG. 76 to FIG. 80) may be defined as the second lower mask pattern 322. Subsequently, the spacer pattern 340 in FIG. 76 to FIG. 80) and the sacrificial pattern 160 (FIG. 76 to FIG. 80) may be etched.

Referring to FIG. 86 to FIG. 89, with continued reference to FIGS. 81-85, the insulating material layer 105M (FIG. 81 to FIG. 85) may be etched using the first lower mask pattern 321 and the second lower mask pattern 322 as the mask. After this etching process has been completed, the remaining portion of the insulating material layer 105M (FIG. 81 to FIG. 85) may be defined as the insulating pattern 305. In some example embodiments, a portion of the etching stop layer 101 between the insulating patterns 305 may be exposed.

Referring to FIG. 30 to FIG. 34, the plurality of wiring patterns may be respectively formed between the insulating patterns 305 and on the upper surface of the etching stop layer 101. For example, the plurality of wiring patterns may include the first to seventh wiring patterns 111, 112, 313, 114, 115, 116, and 117. For example, each of the first to seventh wiring patterns 111, 112, 313, 114, 115, 116 and 117 may extend in the second horizontal direction DR2. For example, the third wiring pattern 313 may include the eighth wiring pattern 318 and the ninth wiring pattern 319 spaced from each other in the second horizontal direction DR2. For example, the eighth wiring pattern 318 may be disposed between the second wiring pattern 112 and each of the fourth and fifth wiring patterns 114 and 115. The ninth wiring pattern 319 may be disposed between the second wiring pattern 112 and the fifth wiring pattern 115. The ninth wiring pattern 319 may be spaced from the eighth wiring pattern 318 in the second horizontal direction DR2.

In some example embodiments, the pitch P1 in the second horizontal direction DR2 between the fourth wiring pattern 114 and the fifth wiring pattern 115 may be equal to the pitch P2 in the second horizontal direction DR2 between the eighth wiring pattern 318 and the ninth wiring pattern 319. In some example embodiments, the pitch P2 in the second horizontal direction DR2 between the eighth wiring pattern 318 and the ninth wiring pattern 319 may be equal to the width in the second horizontal direction DR2 of the spacer material layer 340M that fills the second trench T2 (FIG. 48). For example, the pitch in the second horizontal direction DR2 between the fourth wiring pattern 114 and the fifth wiring pattern 115 may be equal to the width in the second horizontal direction DR2 of the sacrificial pattern 160 (FIG. 76 to FIG. 80). Using the fabricating process, according to the some example embodiments discussed above, the semiconductor device as shown in FIG. 30 to FIG. 34 may be fabricated.

Hereinafter, a semiconductor device according to some example embodiments of the inventive concepts is described with reference to FIG. 90.

FIG. 90 is a layout illustrating an example semiconductor device.

Referring to FIG. 90, in the semiconductor device according to some example embodiments of the inventive concepts, each of an end 414E of the fourth wiring pattern 414, an end 415E of the fifth wiring pattern 415, an end 418E of an eighth wiring pattern 418, and an end 419E of a ninth wiring pattern 419 may include a curved or rounded edge.

For example, a portion of the end 414E of the fourth wiring pattern 414 facing the fifth wiring pattern 415 may include a curved or rounded edge. A portion of the end 415E of the fifth wiring pattern 415 facing the fourth wiring pattern 414 may include a curved or rounded edge. Each of a width W1 in the second horizontal direction DR2 of the end 414E of the fourth wiring pattern 414 including the curved surface and a width W2 in the second horizontal direction DR2 of the end 415E of the fifth wiring pattern 415 including the curved or rounded edge may be 7 nm or less.

For example, the third wiring pattern 413 may include the eighth wiring pattern 418 and the ninth wiring pattern 419 spaced from each other in the second horizontal direction DR2. The ninth wiring pattern 419 may be spaced from the eighth wiring pattern 418 in the second horizontal direction DR2. A portion of the end 418E of the eighth wiring pattern 418 facing the ninth wiring pattern 419 may include a curved or rounded edge. A portion of the end 419E of the ninth wiring pattern 419 facing the eighth wiring pattern 418 may include a curved or rounded edge. For example, each of a width W3 in the second horizontal direction DR2 of the end 418E of the eighth wiring pattern 418 including the curved or rounded edge and a width W4 in the second horizontal direction DR2 of the end 419E of the ninth wiring pattern 419 including the curved or rounded edge may be 7 nm or less.

For example, when each of the width W1 in the second horizontal direction DR2 of the end 414E of the fourth wiring pattern 414, the width W2 in the second horizontal direction DR2 of the end 415E of the fifth wiring pattern 415, the width W3 in the second horizontal direction DR2 of the end 418E of the eighth wiring pattern 418, and the width W4 in the second horizontal direction DR2 of the end 419E of the ninth wiring pattern 419 is 0 or close to 0, the semiconductor device as shown in FIG. 30 to FIG. 34 may be achieved.

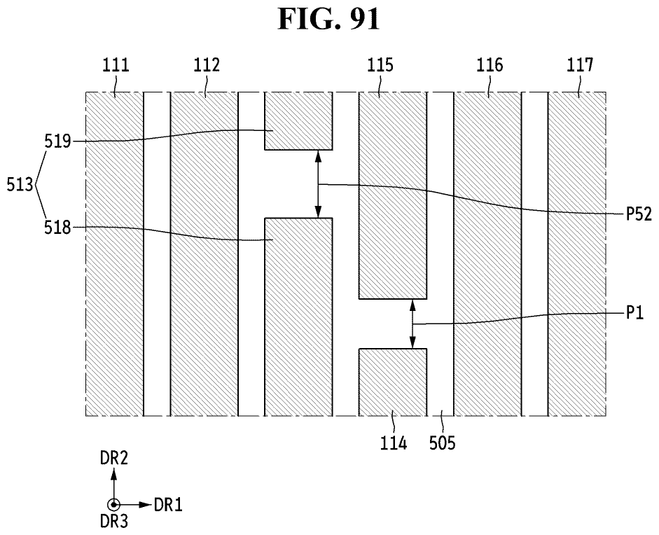

Hereinafter, a semiconductor device according to some example embodiments of the inventive concepts is described with reference to FIG. 91.

FIG. 91 is a layout illustrating a semiconductor device according to some example embodiments of the inventive concepts. Referring to FIG. 91, in the semiconductor device according to some example embodiments of the inventive concepts, a pitch P52 in the second horizontal direction DR2 between an eighth wiring pattern 518 and a ninth wiring pattern 519 may be different from the pitch P1 in the second horizontal direction DR2 between the fourth wiring pattern 114 and the fifth wiring pattern 115.

For example, a third wiring pattern 513 may include the eighth wiring pattern 518 and the ninth wiring pattern 519 spaced from each other in the second horizontal direction DR2. The ninth wiring pattern 519 may be spaced from the eighth wiring pattern 518 in the second horizontal direction DR2. For example, the fifth wiring pattern 115 may be spaced from the fourth wiring pattern 114 in the second horizontal direction DR2. For example, the pitch P52 in the second horizontal direction DR2 between the eighth wiring pattern 518 and the ninth wiring pattern 519 may be larger than the pitch P1 in the second horizontal direction DR2 between the fourth wiring pattern 114 and the fifth wiring pattern 115. For example, the insulating pattern 505 may surround the sidewall of each of the first to seventh wiring patterns 111, 112, 513, 114, 115, 116, and 117.

Hereinafter, a method for fabricating a semiconductor device according to some example embodiments of the inventive concepts is described with reference to FIG. 91 to FIG. 93

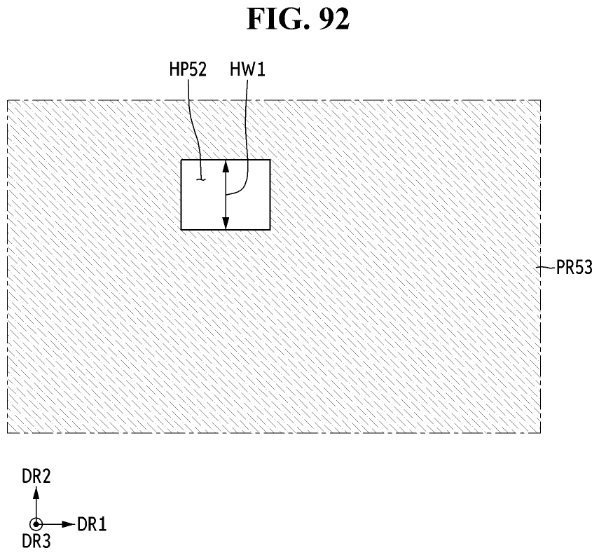

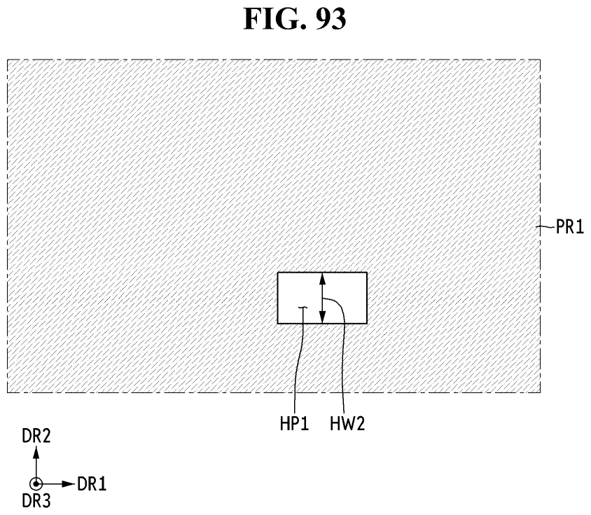

FIG. 92 and FIG. 93 illustrate intermediate structures corresponding to intermediate operations of a method for fabricating a semiconductor device according to some example embodiments of the inventive concepts.

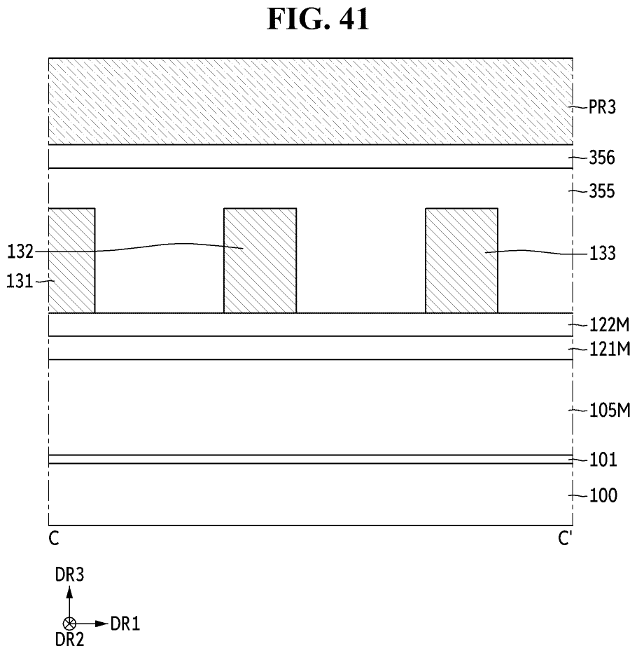

Referring to FIG. 92, after performing the fabricating process as shown in FIG. 35 to FIG. 39, the fifth upper mask material layer 355 (FIG. 41 to FIG. 44) and the sixth upper mask material layer 356 (FIG. 41 to FIG. 44) may be sequentially formed on the upper surface of the second lower mask material layer 122M (FIG. 41 to FIG. 44), and each of the first to third middle mask patterns 131, 132, and 133 (FIG. 41 to FIG. 44). Subsequently, a third photoresist pattern PR53 including a second hole pattern HP52 may be formed on an upper surface of the sixth upper mask material layer 356 (FIG. 41 to FIG. 44). For example, the second hole pattern HP52 may have a width HW1 in the second horizontal direction DR2.

Referring to FIG. 93, after performing the fabricating process as shown in FIG. 45 to FIG. 53, the first upper mask material layer 151 (FIG. 55 to FIG. 58) and the second upper mask material layer 152 (FIG. 55 to FIG. 58) may be formed sequentially on the upper surface of the spacer material layer 340M (FIG. 55 to FIG. 58). Subsequently, the first photoresist pattern PR1 including the first hole pattern HP1 may be formed on the upper surface of the second upper mask material layer 152 (FIG. 55 to FIG. 58). For example, the first hole pattern HP1 may have a width HW2 in the second horizontal direction DR2. For example, the width HW2 in the second horizontal direction DR2 of the first hole pattern HP1 may be smaller than the width HW1 in the second horizontal direction DR2 of the second hole pattern HP52. Subsequently, the fabricating process as shown in FIG. 59 to FIG. 89 and FIG. 91 may be performed such that the semiconductor device as shown in FIG. 91 may be fabricated.

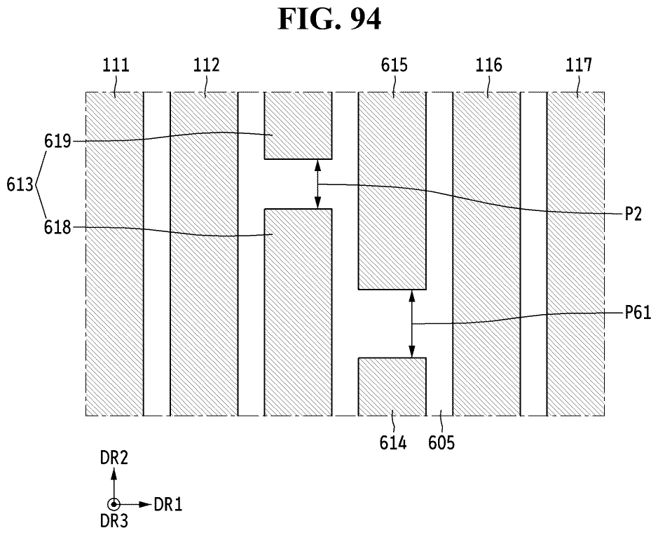

FIG. 94 illustrates a layout of a semiconductor device according to some example embodiments of the inventive concepts.

Referring to FIG. 94, a pitch P2 in the second horizontal direction DR2 between an eighth wiring pattern 618 and a ninth wiring pattern 619 may be different from a pitch P61 in the second horizontal direction DR2 between a fourth wiring pattern 614 and a fifth wiring pattern 615.

For example, a third wiring pattern 613 may include the eighth wiring pattern 618 and the ninth wiring pattern 619 spaced from each other in the second horizontal direction DR2. The ninth wiring pattern 619 may be spaced from the eighth wiring pattern 618 in the second horizontal direction DR2. For example, the fifth wiring pattern 615 may be spaced from the fourth wiring pattern 614 in the second horizontal direction DR2. In some example embodiments, the pitch P2 in the second horizontal direction DR2 between the eighth wiring pattern 618 and the ninth wiring pattern 619 may be smaller than the pitch P61 in the second horizontal direction DR2 between the fourth wiring pattern 614 and the fifth wiring pattern 615. In some example embodiments, the insulating pattern 605 may surround the sidewall of each of the first to seventh wiring patterns 111, 112, 613, 614, 615, 116, and 117.

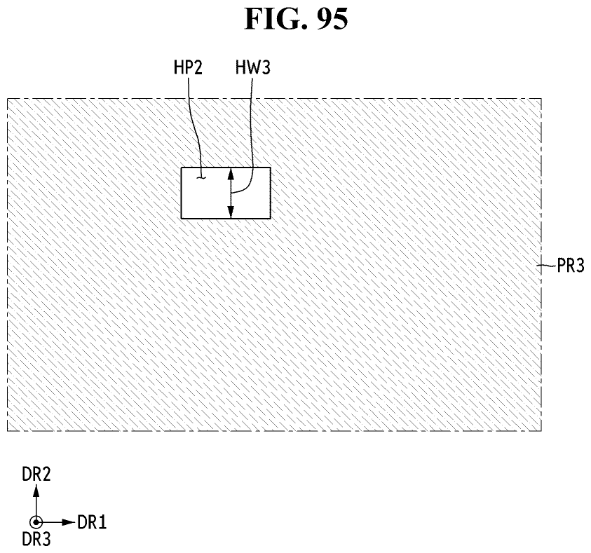

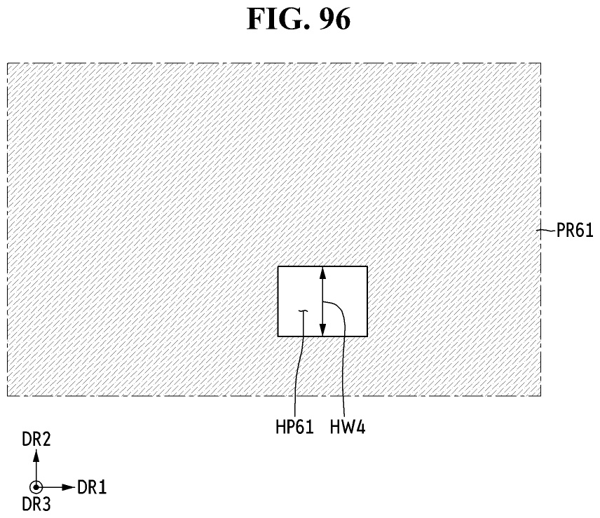

FIG. 95 and FIG. 96 illustrate intermediate structures corresponding to intermediate operations of a method for fabricating a semiconductor device according to some example embodiments of the inventive concepts.

Referring to FIG. 95, after performing the fabricating process as shown, for example, in FIG. 35 to FIG. 39, the fifth upper mask material layer 355 (FIG. 41 to FIG. 44) and the sixth upper mask material layer 356 (FIG. 41 to FIG. 44) may be formed sequentially on the upper surface of the second lower mask material layer 122M (FIG. 41 to FIG. 44), and each of the first to third middle mask patterns 131, 132, and 133 (FIG. 41 to FIG. 44). Subsequently, the third photoresist pattern PR3 including the second hole pattern HP2 may be formed on the upper surface of the sixth upper mask material layer 356 (FIG. 41 to FIG. 44). In some example embodiments, the second hole pattern HP2 may have a width HW3 in the second horizontal direction DR2.

Referring to FIG. 96, after performing the fabricating process as shown, for example, in FIG. 45 to FIG. 53, the first upper mask material layer 151 (FIG. 55 to FIG. 58) and the second upper mask material layer 152 (FIG. 55 to FIG. 58) may be formed sequentially on the upper surface of the spacer material layer 340M (FIG. 55 to FIG. 58). Subsequently, a first photoresist pattern PR61 including a first hole pattern HP61 may be formed on the upper surface of the second upper mask material layer 152 (FIG. 55 to FIG. 58). For example, the first hole pattern HP61 may have a width HW4 in the second horizontal direction DR2. For example, the width HW4 in the second horizontal direction DR2 of the first hole pattern HP61 may be greater than the width HW3 in the second horizontal direction DR2 of the second hole pattern HP2. Subsequently, the fabricating process as shown, for example, in FIG. 59 to FIG. 89 and FIG. 94 may be performed such that the semiconductor device as shown in FIG. 94 may be fabricated.

While several example embodiments have discussed herein, it should be understood that the disclosed devices and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A method for fabricating a semiconductor device, the method comprising:
sequentially forming an insulating material layer and a lower mask material layer on an upper surface of a substrate;
forming a first middle mask pattern and a second middle mask pattern on an upper surface of the lower mask material layer, wherein the second middle mask pattern is spaced apart from the first middle mask pattern in a first horizontal direction, and each of the first and second middle mask patterns extend in a second horizontal direction different from the first horizontal direction;
forming a spacer material layer on each of the upper surface of the lower mask material layer, a sidewall and an upper surface of the first middle mask pattern, and a sidewall and an upper surface of the second middle mask pattern;
forming a first upper mask material layer on an upper surface of the spacer material layer;
forming a first photoresist pattern having a first hole pattern on an upper surface of the first upper mask material layer, the first hole pattern exposing a portion of the first upper mask material layer between the first and second middle mask patterns;
etching the first upper mask material layer through the first hole pattern to form a first trench exposing a portion of the spacer material layer between the first and second middle mask patterns;
forming a sacrificial pattern on the spacer material layer in the first trench;
etching the first upper mask material layer;
etching the portion of the spacer material layer such that a portion of the upper surface of the lower mask material layer between the first and second middle mask patterns is exposed, wherein a portion of the spacer material layer remaining on the sidewall of each of the first and second middle mask patterns and a lower surface of the sacrificial pattern forms a spacer pattern;
etching the first and second middle mask patterns;
etching the lower mask material layer using the spacer pattern and the sacrificial pattern as a mask, wherein a remaining portion of the lower mask material layer forms a lower mask pattern;
etching the insulating material layer using the lower mask pattern as a mask, wherein a remaining portion of the insulating material layer forms an insulating pattern; and
forming each of a plurality of wiring patterns between adjacent ones of the insulating patterns,
wherein the plurality of wiring patterns include a first wiring pattern, a second wiring pattern spaced apart from the first wiring pattern in the first horizontal direction, and a third wiring pattern spaced apart from the second wiring pattern in the second horizontal direction.

2. The method of claim 1, wherein forming of the spacer material layer comprises forming the spacer material layer conformally.

3. The method of claim 1, wherein forming of the first photoresist pattern including the first hole pattern comprises forming the first photoresist pattern such that a width in the first horizontal direction of the first hole pattern is less than a pitch in the first horizontal direction between the first and second middle mask patterns.

4. The method of claim 1, wherein forming of the first trench comprises exposing at least a portion of an uppermost surface of the spacer material layer through the first trench.

5. The method of claim 1, wherein a pitch in the second horizontal direction between the second wiring pattern and third wiring pattern is equal to a width in the second horizontal direction of the sacrificial pattern.

6. The method of claim 1, wherein the sacrificial pattern includes a material different from a material of the spacer material layer.

7. The method of claim 1, wherein forming of the lower mask material layer comprises:
forming a first lower mask material layer on an upper surface of the insulating material layer; and
forming a second lower mask material layer on an upper surface of the first lower mask material layer, the second lower mask material layer including a material different from a material of the first lower mask material layer.

8. The method of claim 1, further comprising:
before the forming of the spacer material layer, forming a second upper mask material layer on the upper surface of the lower mask material layer, and each of the first and second middle mask patterns;
forming a second photoresist pattern having a second hole pattern on an upper surface of the second upper mask material layer, a second hole pattern exposing a portion of the second upper mask material layer on the upper surface of the first middle mask pattern; and
etching each of the second upper mask material layer and the first middle mask pattern through the second hole pattern to form a second trench exposing a portion of the upper surface of the lower mask material layer,
wherein the first middle mask pattern includes third and fourth middle mask patterns spaced from each other in the second horizontal direction through the second trench.

9. The method of claim 8, wherein forming of the spacer material layer further comprises forming the spacer material layer so as to fill the second trench.

10. The method of claim 9, wherein the first wiring pattern includes a fourth wiring pattern and a fifth wiring pattern spaced apart from the fourth wiring pattern in the second horizontal direction, and
wherein a pitch in the second horizontal direction between the fourth and fifth wiring patterns is equal to a width in the second horizontal direction of the spacer material layer filling the second trench.

11. The method of claim 8, wherein the first hole pattern is at least partially offset from the second hole pattern in each of the first and second horizontal directions.

12. The method of claim 8, wherein a width in the second horizontal direction of the first hole pattern is less than a width in the second horizontal direction of the second hole pattern.

13. A method for fabricating a semiconductor device, the method comprising:
sequentially forming an insulating material layer and a lower mask material layer on an upper surface of a substrate;
forming a first middle mask pattern and a second middle mask pattern on an upper surface of the lower mask material layer, wherein the second middle mask pattern is spaced apart from the first middle mask pattern in a first horizontal direction, and each of the first middle mask pattern and the second middle mask pattern extend in a second horizontal direction different from the first horizontal direction;
conformally forming a spacer material layer on each of the upper surface of the lower mask material layer, a sidewall and an upper surface of the first middle mask pattern, and a sidewall and an upper surface of the second middle mask pattern;
forming a first photoresist pattern having a first hole pattern on the spacer material layer between the first and second middle mask patterns;
forming a first trench under the first hole pattern, the first trench defined by the spacer material layer;
forming a sacrificial pattern on the spacer material layer in the first trench;
etching a portion of the spacer material layer such that a portion of the upper surface of the lower mask material layer between the first and second middle mask patterns is exposed, wherein a portion of the spacer material layer remaining on the sidewall of each of the first and second middle mask patterns and a lower surface of the sacrificial pattern forms a spacer pattern;
etching the first and second middle mask patterns;
etching the lower mask material layer using the spacer pattern and the sacrificial pattern as a mask, wherein a remaining portion of the lower mask material layer forms a lower mask pattern;
etching the insulating material layer using the lower mask pattern as a mask, wherein a remaining portion of the insulating material layer forms an insulating pattern; and
forming each of a plurality of wiring patterns between adjacent ones of the insulating patterns,
wherein the sacrificial pattern includes a material different from a material of the spacer material layer.

14. The method of claim 13, wherein the plurality of wiring patterns include a first wiring pattern, a second wiring pattern spaced apart from the first wiring pattern in the first horizontal direction, and a third wiring pattern spaced apart from the second wiring pattern in the second horizontal direction, and
wherein a pitch in the second horizontal direction between the second and third wiring patterns is equal to a width in the second horizontal direction of the sacrificial pattern.

15. The method of claim 13, wherein the forming of the first photoresist pattern having the first hole pattern comprises,
forming the first photoresist pattern such that the first hole pattern is at least partially offset from each of the first and second middle mask patterns in a vertical direction.

16. The method of claim 13, wherein etching of the portion of the spacer material layer to expose the portion of the upper surface of the lower mask material layer between the first and second middle mask patterns comprises,
etching a portion of the spacer material layer formed on the upper surface of each of the first and second middle mask patterns to expose the upper surface of each of the first and second middle mask patterns.

17. The method of claim 13, further comprising:
before the conformally forming of the spacer material layer,
forming a second photoresist pattern having a second hole pattern on the upper surface of the first middle mask pattern; and
etching the first middle mask pattern through the second hole pattern to form a second trench exposing a portion of the upper surface of the lower mask material layer,
wherein the first middle mask pattern includes third and fourth middle mask patterns spaced from each other in the second horizontal direction through the second trench.

18. The method of claim 17, wherein a width in the second horizontal direction of the first hole pattern is greater than a width in the second horizontal direction of the second hole pattern.

19. The method of claim 13, wherein sequentially forming of the insulating material layer and the lower mask material layer on the upper surface of the substrate comprises forming an etching stop layer between the upper surface of the substrate and the insulating material layer.

20. A method for fabricating a semiconductor device, the method comprising:
sequentially forming an insulating material layer, a first lower mask material layer, and a second lower mask material layer on an upper surface of a substrate;
forming first and second middle mask patterns on an upper surface of the second lower mask material layer, the second middle mask pattern spaced apart from the first middle mask pattern in a first horizontal direction, each of the first and second middle mask patterns extending in a second horizontal direction different from the first horizontal direction;
conformally forming a spacer material layer on each of the upper surface of the second lower mask material layer, a sidewall and an upper surface of the first middle mask pattern, and a sidewall and an upper surface of the second middle mask pattern;
forming a first upper mask material layer on an upper surface of the spacer material layer;
forming a first photoresist pattern having a first hole pattern exposing a portion of the first upper mask material layer between the first and second middle mask patterns on an upper surface of the first upper mask material layer, wherein a width in the first horizontal direction of the first hole pattern is less than a pitch in the first horizontal direction between the first and second middle mask patterns;
etching the first upper mask material layer through the first hole pattern to form a first trench exposing a portion of the spacer material layer between the first and second middle mask patterns;
forming a sacrificial pattern on the spacer material layer in the first trench;
etching the first upper mask material layer;
etching a portion of the spacer material layer such that a portion of the upper surface of the second lower mask material layer between the first and second middle mask patterns is exposed, wherein a portion of the spacer material layer remaining on the sidewall of each of the first and second middle mask patterns and a lower surface of the sacrificial pattern forms a spacer pattern;
etching the first and second middle mask patterns;
etching each of the first and second lower mask material layers using the spacer pattern and the sacrificial pattern as a mask, wherein remaining portions of the first and second lower mask material layers form a first lower mask pattern and a second lower mask pattern, respectively;
etching the insulating material layer using the first and second lower mask patterns as a mask, wherein a remaining portion of the insulating material layer forms an insulating pattern; and
forming each of a plurality of wiring patterns between adjacent ones of the insulating patterns,
wherein the plurality of wiring patterns include a first wiring pattern, a second wiring pattern spaced apart from the first wiring pattern in the first horizontal direction, and a third wiring pattern spaced apart from the second wiring pattern in the second horizontal direction,
wherein a pitch in the second horizontal direction between the second and third wiring patterns is equal to a width in the second horizontal direction of the sacrificial pattern, and
wherein the sacrificial pattern includes a material different from a material of the spacer material layer.
